(19) United States
(12) Patent Application Publication
(10) Pub. No.: US 2026/0101577 A1
(43) Pub. Date: Apr. 9, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Guan-Lin CHEN, Hsinchu (TW); Chun Yi CHOU, Hsinchu (TW); Kuo-Cheng CHIANG, Hsinchu (TW); Shi Ning JU, Hsinchu (TW); Chih-Hao WANG, Hsinchu (TW)

(21) Appl. No.: 19/047,694

(22) Filed: Feb. 7, 2025

Related U.S. Application Data
(60) Provisional application No. 63/703,970, filed on Oct. 6, 2024.

(51) Int. Cl. H10D 84/83; H10D 30/00; H10D 30/01; H10D 30/43; H10D 62/10; H10D 62/13; H10D 62/832; H10D 64/68

(52) U.S. Cl. CPC H10D 84/832; H10D 30/014; H10D 30/0191; H10D 30/43; H10D 30/502; H10D 62/121; H10D 62/151; H10D 62/832; H10D 64/685

(57) ABSTRACT

Embodiments of the present disclosure provide a semiconductor device structure and methods for forming the same. The structure includes a first semiconductor layer disposed in a first region and a second semiconductor layer surrounding the first semiconductor layer in the first region. The first and second semiconductor layers comprise different materials. The structure further includes a first gate electrode layer surrounding a portion of the second semiconductor layer, a first source/drain region electrically connected to the second semiconductor layer, and a second source/drain region electrically connected to the second semiconductor layer. The second semiconductor layer is disposed between the first and second source/drain regions.

### CROSS-REFERENCE TO RELATED APPLICATIONS

This application claims priority to U.S. Provisional Application Ser. No. 63/703,970 filed Oct. 6, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIGS. 6, 7, 8, 9, 10, 11, 12, 13, 14, 15, and 16 are cross-sectional side views of various stages of manufacturing the semiconductor device structure taken along line A-A of FIG. 5, in accordance with some embodiments.

FIG. 12-1 is a cross-sectional side view of one of various stages of manufacturing the semiconductor device structure taken along line B-B of FIG. 5, in accordance with some embodiments.

FIG. 12-2 is a chart showing a germanium concentration profile in a cap layer and a first semiconductor layer, in accordance with some embodiments.

FIGS. 17, 18, and 19 are cross-sectional side views of various stages of manufacturing the semiconductor device structure taken along line B-B of FIG. 5, in accordance with some embodiments.

FIG. 20 is a cross-sectional side view of one of various stages of manufacturing the semiconductor device structure taken along line A-A of FIG. 5, in accordance with some embodiments.

FIG. 21 is a cross-sectional top view of one of various stages of manufacturing the semiconductor device structure, in accordance with some embodiments.

FIG. 22 is a cross-sectional side view of one of various stages of manufacturing the semiconductor device structure taken along line A-A of FIG. 5, in accordance with alternative embodiments.

FIGS. 23, 24, 25, 26, and 27 are cross-sectional side views of various stages of manufacturing the semiconductor device structure taken along line A-A of FIG. 5, in accordance with alternative embodiments.

FIGS. 28, 29, and 30 are cross-sectional side views of various stages of manufacturing the semiconductor device structure taken along line B-B of FIG. 5, in accordance with alternative embodiments.

FIG. 31 is a cross-sectional side view of one of various stages of manufacturing the semiconductor device structure taken along line A-A of FIG. 5, in accordance with alternative embodiments.

FIG. 32 is a cross-sectional top view of one of various stages of manufacturing the semiconductor device structure, in accordance with alternative embodiments.

FIG. 33 is a cross-sectional side view of one of various stages of manufacturing the semiconductor device structure taken along line A-A of FIG. 5, in accordance with alternative embodiments.

FIGS. 34, 35, 36, and 37 are cross-sectional side views of various stages of manufacturing the semiconductor device structure taken along line A-A of FIG. 5, in accordance with alternative embodiments.

FIG. 38 is a cross-sectional top view of one of various stages of manufacturing the semiconductor device structure, in accordance with some embodiments.

FIGS. 39, 40, 41, and 42 are cross-sectional side views of various stages of manufacturing the semiconductor device structure taken along line A-A of FIG. 5, in accordance with alternative embodiments.

FIG. 43 is a cross-sectional top view of one of various stages of manufacturing the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

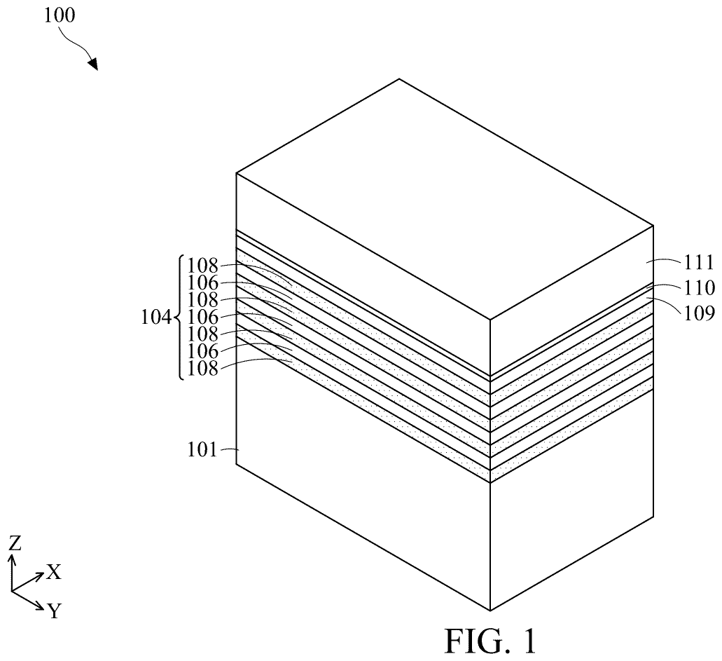

FIG. 1-21 show exemplary processes for manufacturing a semiconductor device structure 100 according to embodiments of the present disclosure. It is understood that additional operations can be provided before, during, and after processes shown by FIG. 1-21, and some of the operations described below can be replaced or eliminated, for additional embodiments of the method. The order of the operations/processes is not limiting and may be interchangeable.

FIGS. 1, 2, 3, 4, and 5 are perspective views of various stages of manufacturing a semiconductor device structure 100, in accordance with some embodiments. As shown in FIG. 1, a semiconductor device structure 100 includes a stack of semiconductor layers 104 and a dielectric layer 109 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP).

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and four second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

As shown in FIG. 1, the dielectric layer 109 is formed on the stack of semiconductor layers 104. The dielectric layer 109 may include any suitable dielectric material, such as SiN, SiCN, SiOC, or SiOCN. The thickness of the dielectric layer 109 may range from about 1 nm to about 10 nm. As shown in FIG. 1, an oxide layer 110 is formed on the dielectric layer 109, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

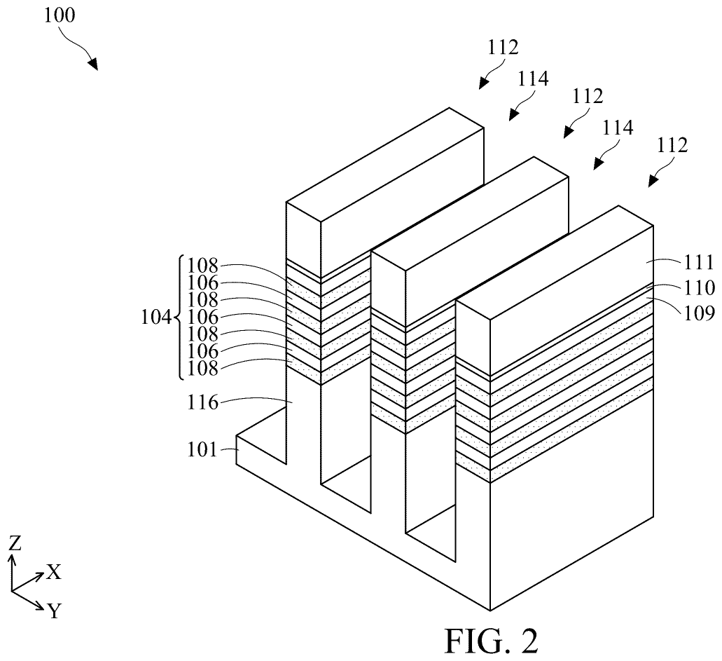

In FIG. 2, fin structures 112 are formed from the stack of semiconductor layers 104 and the dielectric layer 109. Each fin structure 112 has an upper portion including the semiconductor layers 106, 108, the dielectric layer 109, and a substrate portion 116 formed from the substrate 101. The fin structures 112 may be formed by patterning a hard mask layer, such as the oxide layer 110 and the nitride layer 111, using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

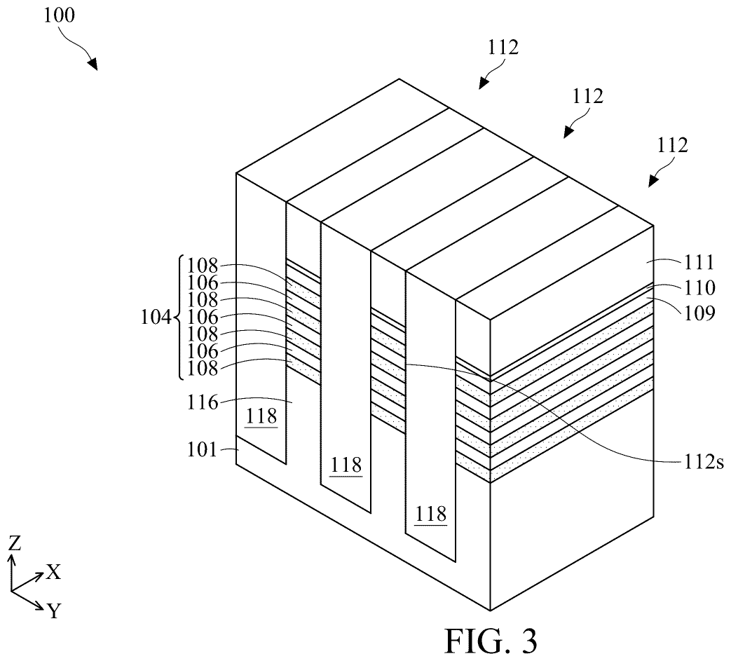

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

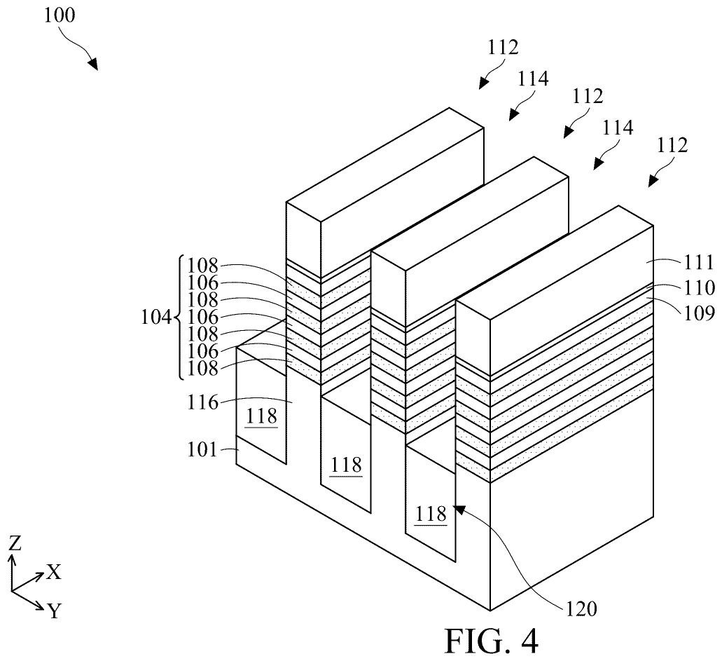

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the shallow trench isolation (STI) regions. The oxide layer 110 and the nitride layer 111 may be removed during the recessing of the insulating material 118 or after the recessing of the insulating material 118, as shown in FIG. 4.

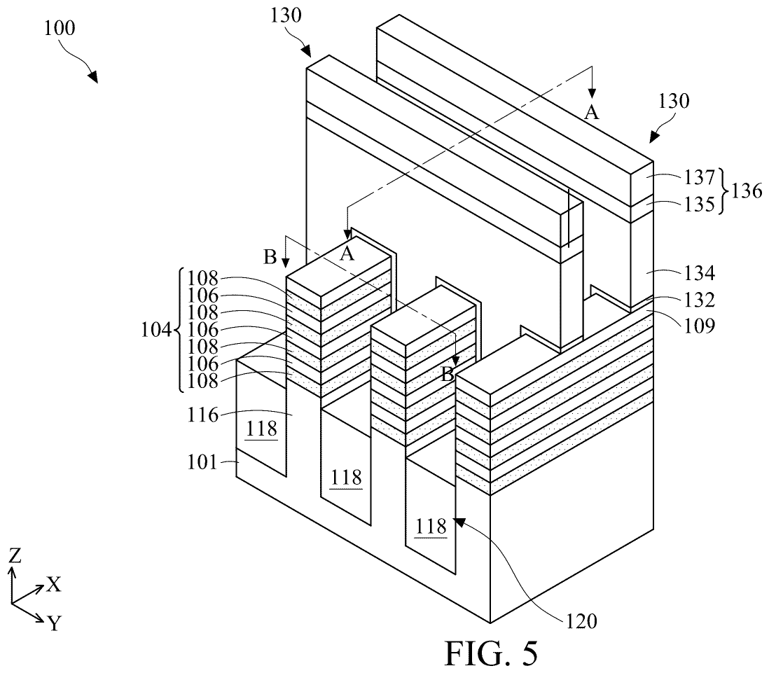

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The first portions of the fin structures 112 that are covered by the sacrificial gate electrode layer 134 of the sacrificial gate structure 130 serve as channel regions for the semiconductor device structure 100.

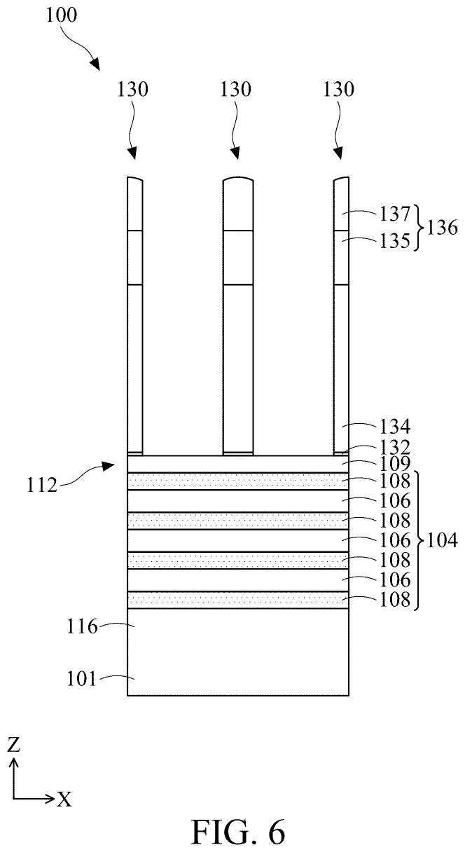

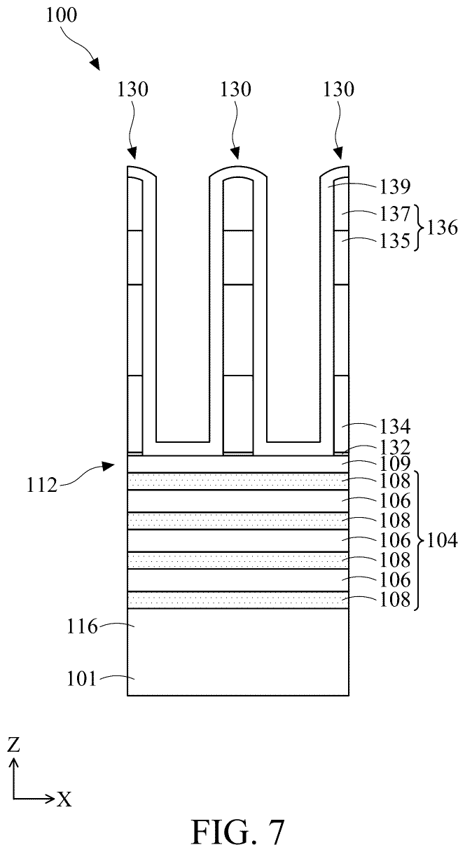

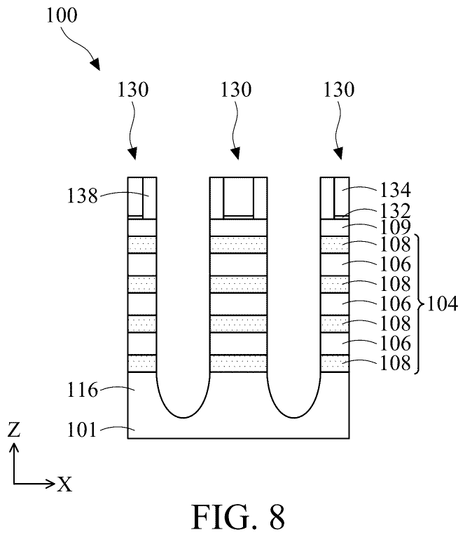

FIGS. 6, 7, 8, 9, 10, 11, 12, 13, 14, 15, and 16 are cross-sectional side views of various stages of manufacturing the semiconductor device structure 100 taken along line A-A of FIG. 5, in accordance with some embodiments. FIG. 6 is a cross-sectional view of the semiconductor device structure 100 shown in FIG. 5. Next, as shown in FIG. 7, a dielectric layer 139 is formed on the semiconductor device structure 100. In some embodiments, the dielectric layer 139 is deposited around the sacrificial gate structures 130. The dielectric layer 139 may include a single layer or multiple layers. The dielectric layer 139 may be made of a dielectric material such as silicon oxide, silicon nitride, silicon carbide, silicon oxynitride, SiCN, silicon oxycarbide, SiOCN, and/or combinations thereof. In some embodiments, the dielectric layer 139 and the dielectric layer 109 include different materials or same materials with different compositions. Next, as shown in FIG. 8, an anisotropic etch process is performed to remove portions of the dielectric layer 139 to form spacers 138 on sidewalls of the sacrificial gate structures 130. The top portion of the sacrificial gate structure 130 is omitted for clarity in FIG. 8 and subsequent figures.

As shown in FIG. 8, after forming the spacers 138, the second portions of the fin structures 112 not covered by the sacrificial gate structure 130 and the spacers 138 are recessed to a level above, at, or below the top surfaces of the isolation regions 120 (FIG. 5). The recessing of the second portions of the fin structures 112 can be done by one or more etch processes. For example, a first etch process may be performed to remove the exposed portions of the dielectric layer 109, and the first etch process may be selective with respect to the material of the dielectric layer 109. Next, a second etch process is performed to remove the portions of the first and second semiconductor layers 106, 108 not covered by the sacrificial gate structures 130 and the spacers 138, and the second etch process may be selective with respect to the semiconductor materials of the first and second semiconductor layers 106, 108. The second etch process may be a dry etch, such as a RIE, NBE, or the like, or a wet etch, such as using tetramethyalammonium hydroxide (TMAH), ammonium hydroxide (NH₄OH), or any suitable etchant.

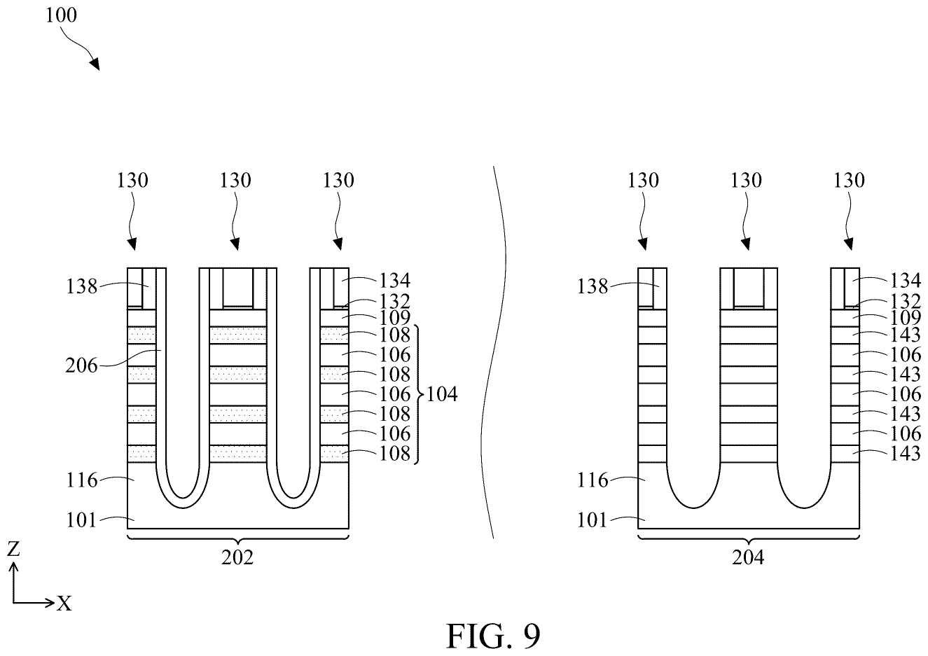

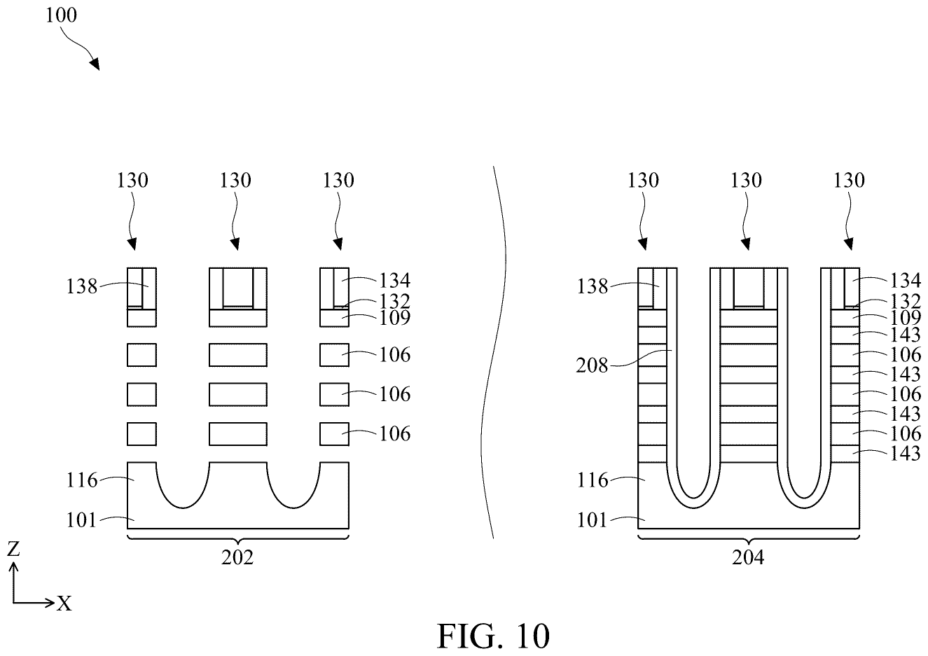

In some embodiments, regions of the semiconductor device structure 100 in which n-type devices or p-type devices are formed are respectively referred to herein as “NMOS regions” or “PMOS regions.” As shown in FIG. 9, the semiconductor device structure 100 includes a PMOS region 202 and an NMOS region 204, and a mask layer 206 is formed in the PMOS region 202. The mask layer 206 may include any suitable material. In some embodiments, the mask layer 206 is a silicon nitride or metal oxide layer and is formed by an ALD process. The mask layer 206 may be initially formed in the PMOS region 202 and the NMOS region 204, and the portion of the mask layer 206 formed in the NMOS region 204 is removed. The portion of the mask layer 206 formed in the PMOS region 202 may be protected by a patterned mask. After forming the mask layer 206 in the PMOS region 202, the second semiconductor layers 108 in the NMOS region 204 are removed and replaced with a dielectric material 143. The second semiconductor layers 108 may be removed by a selective etch process, such as a selective dry etch process, a selective wet etch process, or a combination thereof. In some embodiments, the selective etch process does not substantially affect the first semiconductor layers 106. The removal of the second semiconductor layers 108 form openings between vertically adjacent first semiconductor layers 106, and the dielectric material 143 is formed in the openings and on the exposed surfaces of the semiconductor device structure 100. In some embodiments, the dielectric material 143 is an oxide formed by any suitable process, such as ALD, CVD, PECVD, or FCVD. In some embodiments, the oxide is silicon oxide. Next, as shown in FIG. 9, an etch back process is performed to remove portions of the dielectric material 143 other than the portions of the dielectric material 143 formed between vertically adjacent first semiconductor layers 106. In some embodiments, the etch back process is an anisotropic etching process. At this stage, edge portions of the dielectric material 143 and edge portions of the first semiconductor layers 106 have substantially flat surfaces which may be flush with side surfaces of the spacers 138 and side surfaces of the dielectric layer 109.

In FIG. 10, a mask layer 208 is formed in the NMOS region 204, and the second semiconductor layers 108 in the PMOS region 202 are removed. The mask layer 208 may include the same material as the mask layer 206 and may be formed by the same process as the mask layer 206. The second semiconductor layers 108 may be removed by a selective etch process, such as a selective dry etch process, a selective wet etch process, or a combination thereof. In some embodiments, the selective etch process does not substantially affect the first semiconductor layers 106.

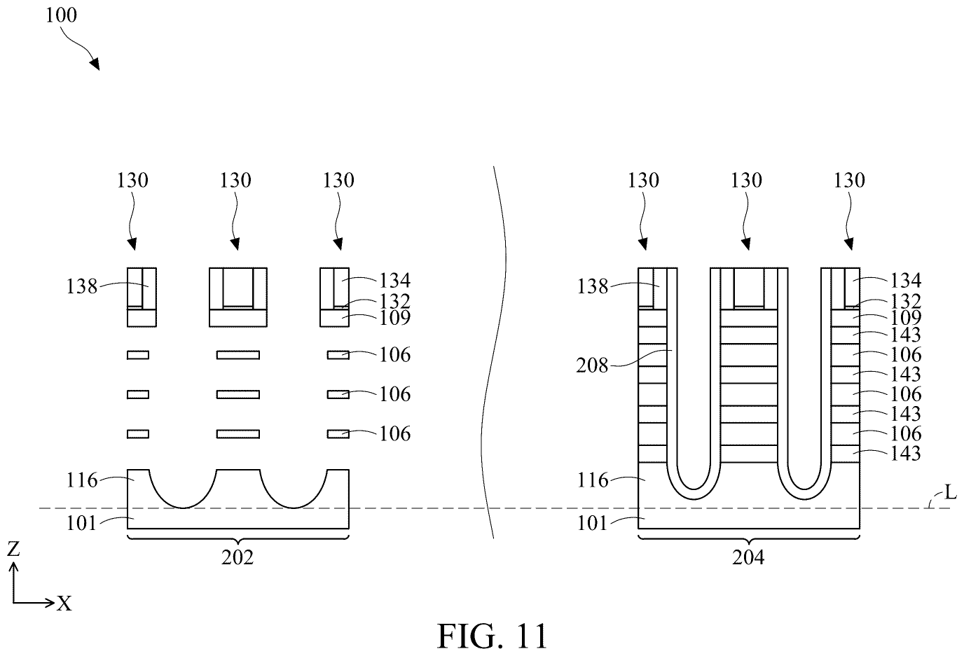

In FIG. 11, a trimming process is performed to reduce the size of the first semiconductor layers 106 in the PMOS region 202. The trimming process may be a selective etch process that does not affect the dielectric materials of the spacers 138, the dielectric layer 109, the insulating material 118 (FIG. 5), and the mask layer 208. In some embodiments, the thickness of the first semiconductor layer 106 is reduced by 0.5 nm to about 5 nm, and the remaining first semiconductor layer 106 has a thickness ranging from about 1 nm to about 5 nm. In some embodiments, the length of the first semiconductor layer 106 along the X direction is also reduced, but the width of the first semiconductor layer 106 along the Y direction is not affected because the first semiconductor layers 106 are in contact with the sacrificial gate dielectric layer 132 (FIG. 5). In some embodiments, the substrate portion 116 is recessed by the trimming process. As shown in FIG. 11, the bottom of a recess in the substrate portion 116 in the PMOS region 202 is located at an imaginary level L, and the bottom of a recess in the substrate portion 116 in the NMOS region 204 is located above the level L. Furthermore, the length of the recess along the X direction in the substrate portion 116 in the PMOS region 202 is greater than the length of the recess in the substrate portion 116 in the NMOS region 204.

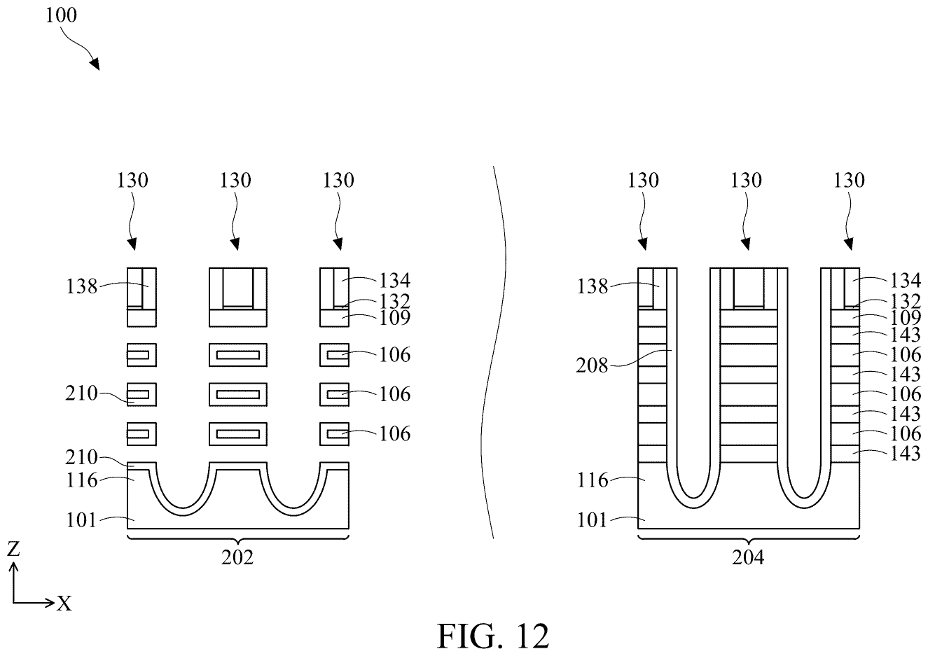

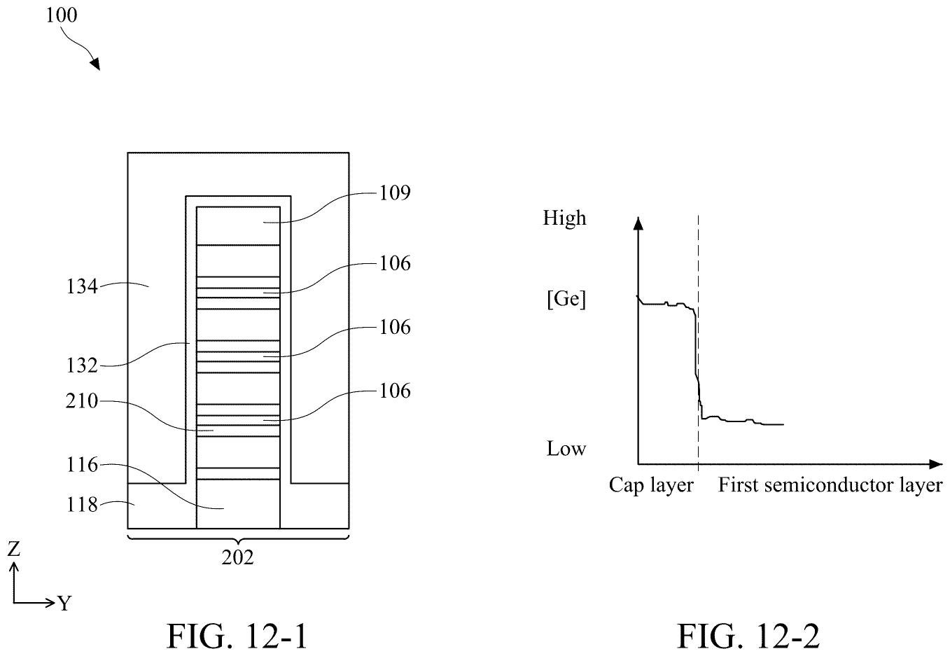

In FIG. 12, a cap layer 210 is formed to surround the first semiconductor layers 106 in the PMOS region 202, and the cap layer 210 is also formed on the substrate portion 116 in the PMOS region 202. The cap layer 210 is a semiconductor layer including any suitable semiconductor material, such as a germanium-containing semiconductor material. In some embodiments, the cap layer 210 is made of or includes SiGe. The SiGe of the cap layer 210 has a closer valence band energy to the effective work function (EWF) value(s) of the PFET gate stack than Si, and thus using SiGe as PFET channel may simplify metal gate patterning (e.g., more work function material options). Furthermore, boron diffusion is more difficult in SiGe than in Si, and thus it is easier to control the concentration distribution of boron to be sharp at interface between the source/drain region and the SiGe channel. In some embodiments, the germanium concentration in the cap layer 210 ranges from about five atomic percent to about 60 atomic percent. If the germanium concentration of the cap layer 210 is less than about five atomic percent, the difference between the cap layer 210 and the first semiconductor layer 106 may be too small to achieve improvements. On the other hand, if the germanium concentration of the cap layer 210 is greater than about 60 atomic percent, the manufacturing cost is increased without significant advantage.

In some embodiments, the cap layer 210 may be epitaxially grown from the semiconductor materials of the first semiconductor layers 106 and the substrate portion 116 in the PMOS region 202, and the cap layer 210 may not be formed on the dielectric materials of the spacers 138, the dielectric layer 109, and the mask layer 208. The cap layer 210 may have a thickness ranging from about 0.5 nm to about 5 nm. In some embodiments, the cap layer 210 has a thickness equal to the thickness of the trimmed portion of the first semiconductor layer 106. After forming the cap layer 210, the mask layer 208 located in the NMOS region 204 may be removed.

FIG. 12-1 is a cross-sectional side view of one of various stages of manufacturing the semiconductor device structure 100 taken along line B-B of FIG. 5, in accordance with some embodiments. As shown in FIG. 12-1, because the edges of the first semiconductor layer 106 along the Y direction are in contact with the sacrificial gate dielectric layer 132, the cap layer 210 is disposed above and below the first semiconductor layer 106 and is not surrounding the first semiconductor layer 106 as shown in the ZX plane shown in FIG. 12.

FIG. 12-2 is a chart showing a germanium concentration profile in the cap layer 210 and the first semiconductor layer 106, in accordance with some embodiments. As shown in FIG. 12-2, there is a sharp drop in the germanium concentration from the cap layer 210 to the first semiconductor layer 106, which means the germanium in the cap layer 210 is not diffused into the first semiconductor layer 106. Subsequent processes do not change the germanium concentration profile.

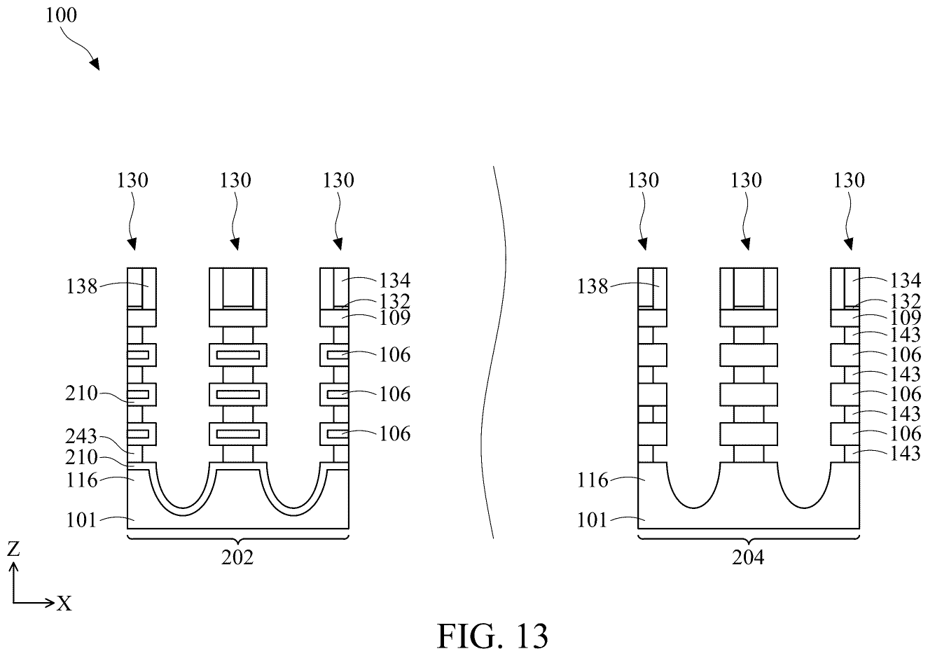

In FIG. 13, a dielectric material 243 is formed between vertically adjacent cap layers 210 in the PMOS region 202. The dielectric material 243 may include the same material as the dielectric material 143 and may be formed by the same process as the dielectric material 143. For example, a conformal dielectric layer is first formed in the PMOS region 202 and the NMOS region 204, and an anisotropic etch process is performed to remove portions of the conformal layer not located between adjacent cap layers 210 in the PMOS region 202 and between the adjacent first semiconductor layers 106 in the NMOS region 204. Next, the dielectric material 243 is laterally recessed to form cavities between the vertically adjacent cap layers 210 in the PMOS region 202, and the dielectric material 143 is laterally recessed to form cavities between the vertically adjacent first semiconductor layers 106 in the NMOS region 204, as shown in FIG. 13. In some embodiments, a single etch process is performed to laterally recess the dielectric materials 143, 243, because the dielectric material 143, 243 include the same material.

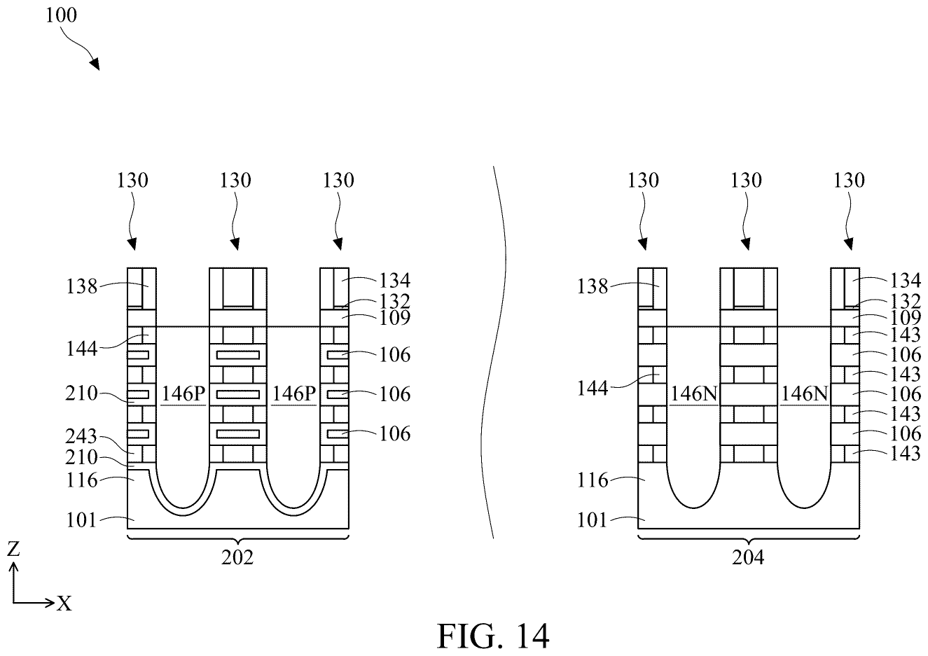

Next, as shown in FIG. 14, a dielectric layer is deposited in the cavities to form dielectric spacers 144 in the PMOS region 202 and the NMOS region 204. The dielectric spacers 144 may be made of a dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the cap layers 210 in the PMOS region and by the first semiconductor layers 106 in the NMOS region 204 during the anisotropic etching process. The dielectric materials 143, 243 are capped between the dielectric spacers 144 along the X direction, as shown in FIG. 14.

As shown in FIG. 14, source/drain (S/D) regions 146P, 146N are formed over the substrate portions 116 in the PMOS region 202 and the NMOS region 204, respectively. In this disclosure, a source region and a drain region are interchangeably used, and the structures thereof are substantially the same. Furthermore, source/drain region(s) may refer to a source or a drain, individually or collectively dependent upon the context. The S/D regions 146P may be epitaxially grown from the cap layer 210, and the S/D regions 146N may be epitaxially grown from the first semiconductor layers 106 and the substrate portions 116. In some embodiments, the S/D regions 146N are n-type S/D epitaxial features and may be made of one or more layers of Si, SiP, SiC and SiCP for n-channel FETs, and the S/D regions 146P are p-type epitaxial features and may be made of one or more layers of Si, SiGe, Ge for p-channel FETs. P-type dopants, such as boron (B), may also be included in the S/D regions 146P. The S/D regions 146P, 146N may be formed by an epitaxial growth method using CVD, ALD or MBE. The S/D regions 146P, 146N may include doped and undoped epitaxial materials. In some embodiments, the S/D regions 146P are electrically connected to the cap layer 210 in the PMOS region 202, and the S/D regions 146N are electrically connected to the first semiconductor layers 106 in the NMOS region 204.

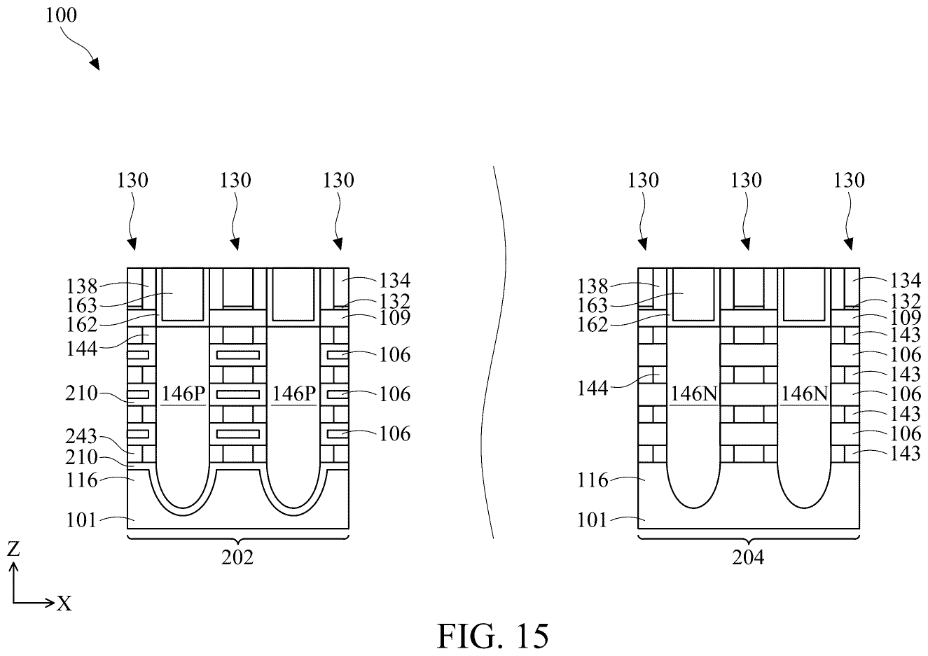

As shown in FIG. 15, a contact etch stop layer (CESL) 162 is conformally formed on the exposed surfaces of the semiconductor device structure 100, and an interlayer dielectric (ILD) layer 163 is formed on the CESL 162. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134. The planarization process may be any suitable process, such as a CMP process. The planarization process removes portions of the ILD layer 163 and the CESL 162 disposed on the sacrificial gate structures 130. The planarization process may also remove the mask layer 136 (FIG. 7).

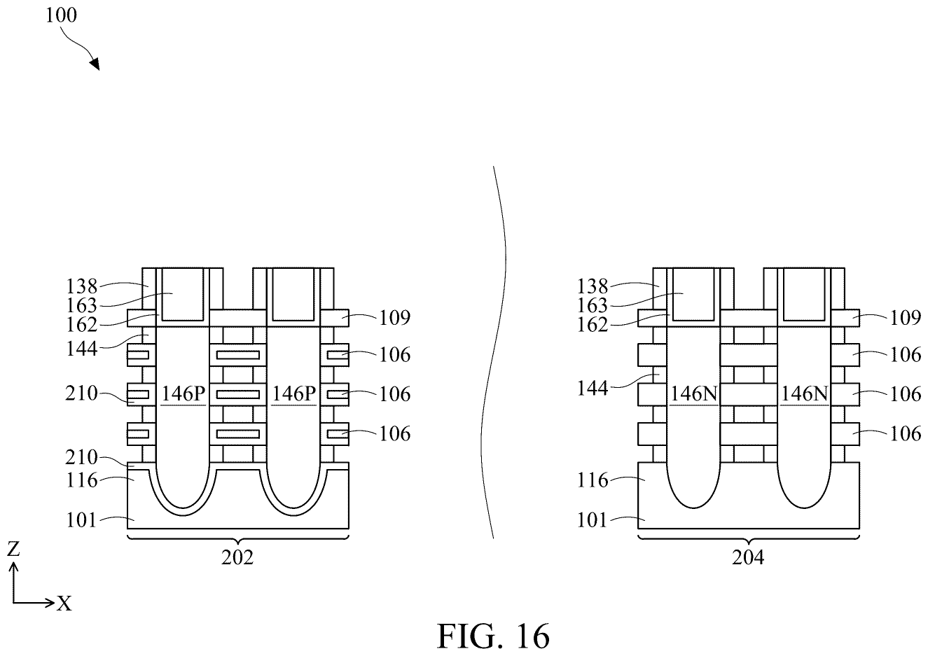

In FIG. 16, the sacrificial gate electrode layer 134, the sacrificial gate dielectric layer 132, and the dielectric materials 143, 243 are removed, exposing portions of the cap layer 210 in the PMOS region 202 and the first semiconductor layer 106 in the NMOS region 204. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 138, the ILD layer 163, and the CESL 162. In some embodiments, the dielectric materials 143, 243 are removed by a selective etch process. The selective etch process removes the dielectric materials 143, 243 but does not remove the first semiconductor layers 106, the cap layer 210, the ILD layer 163, the CESL 162, and the spacers 138. In some embodiments, the sacrificial gate dielectric layer 132 and the dielectric materials 143, 243 are removed by the same selective etch process.

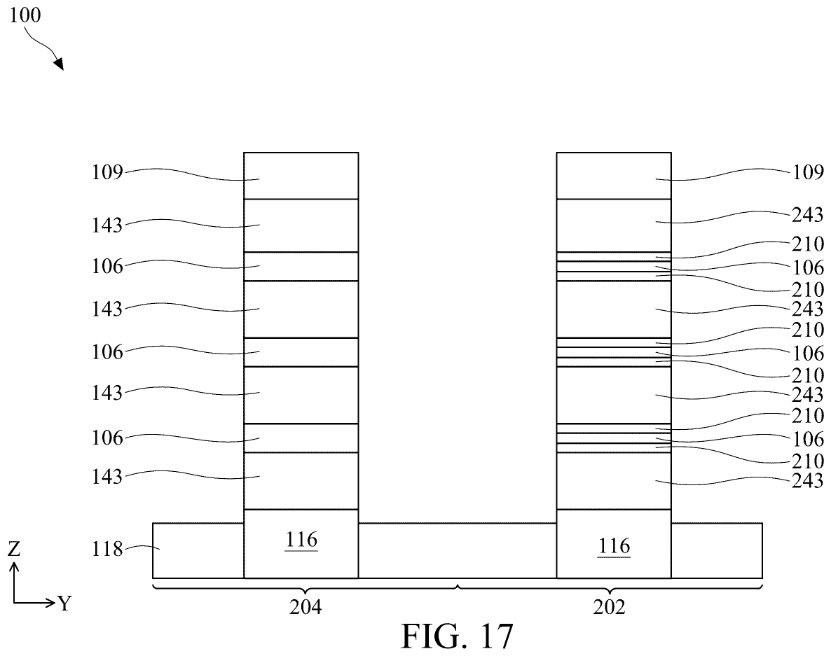

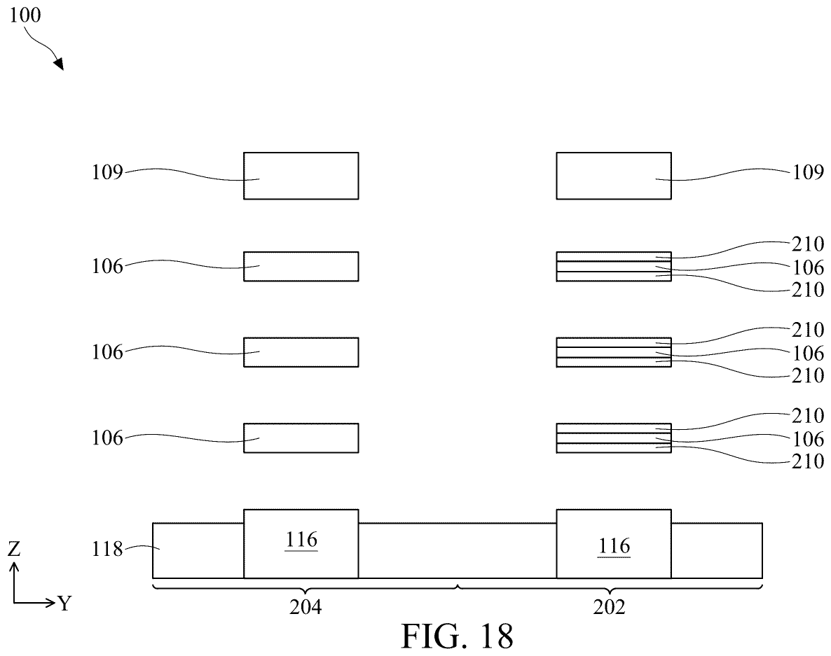

FIGS. 17, 18, and 19 are cross-sectional side views of various stages of manufacturing the semiconductor device structure 100 taken along line B-B of FIG. 5, in accordance with some embodiments. FIG. 17 illustrates the stage of manufacturing the semiconductor device structure 100 after the removal of the sacrificial gate electrode layer 134 and the dielectric layer 132 but before the removal of the dielectric materials 143, 243. Next, as shown in FIG. 18, the dielectric materials 143, 243 are removed.

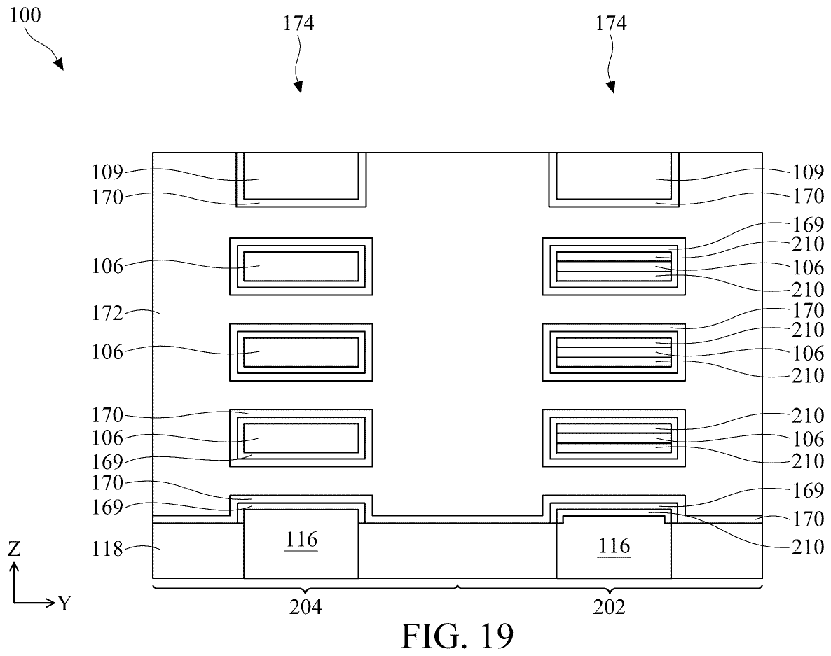

Next, after the formation of the nanostructure channels (i.e., the exposed portions of the cap layer 210 in the PMOS region 202 and the first semiconductor layers 106 in the NMOS region 204), a gate dielectric layer 170 is formed to surround the exposed portions of the first semiconductor layers 106 in the NMOS region 204 and the exposed portions of the cap layer 210 in the PMOS region 202, and a gate electrode layer 172 is formed on the gate dielectric layer 170, as shown in FIG. 19. The gate dielectric layer 170 and the gate electrode layer 172 may be collectively referred to as a gate structure 174. In some embodiments, an interfacial layer (IL) 169 is formed between the gate dielectric layer 170 and the exposed surfaces of the first semiconductor layers 106 in the NMOS region 204 and between the gate dielectric layer 170 and the exposed surfaces of the cap layer 210 in the PMOS region 202. As shown in FIG. 19, the IL 169 is in contact with the top and bottom surfaces of the cap layer 210 and the side surfaces of the cap layer 210 and the first semiconductor layer 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 163. The gate dielectric layer 170 and the gate electrode layer 172 formed over the ILD layer 163 are then removed by using, for example, CMP, until the top surface of the ILD layer 163 is exposed.

In some embodiments, the gate dielectric layer 170 initially surrounds the dielectric layer 109. The IL 169 may be selectively formed around the semiconductor materials of the first semiconductor layers 106 and the cap layer 210, and the IL 169 is not formed between the dielectric layer 109 and the gate dielectric layer 170, as shown in FIG. 19. The CMP process to remove the gate dielectric layer 170 and the gate electrode layer 172 formed over the ILD layer 163 may also remove the gate dielectric layer 170 formed on the top surface of the dielectric layer 109, as shown in FIG. 19. In some embodiments, the dielectric layer 109 serves as an etch stop layer during the CMP process.

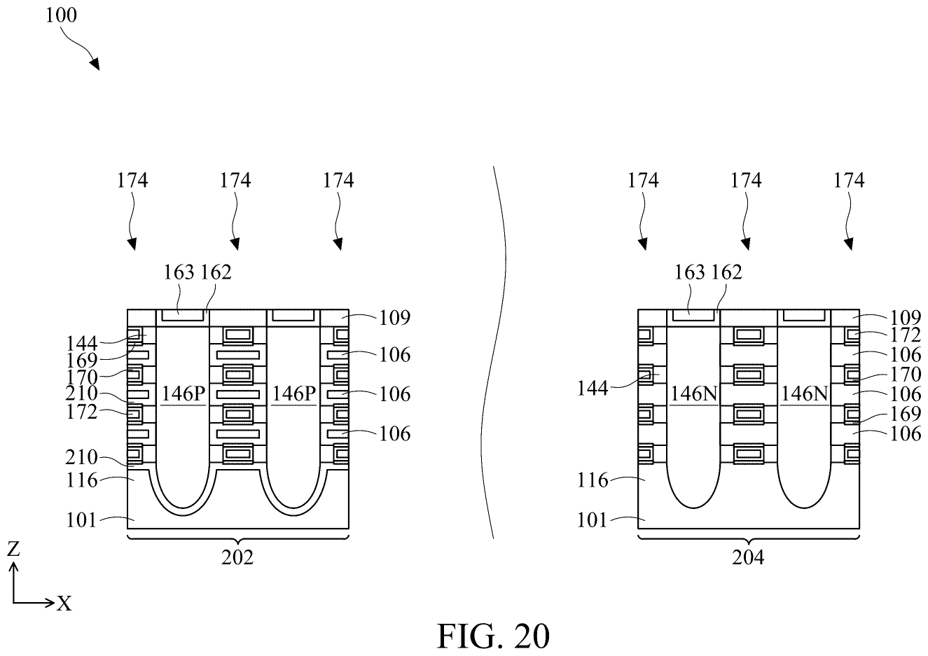

FIG. 20 is a cross-sectional side view of one of various stages of manufacturing the semiconductor device structure 100 taken along line A-A of FIG. 5, in accordance with some embodiments. FIG. 20 illustrates the semiconductor device structure 100 at the same manufacturing stage as the semiconductor device structure 100 shown in FIG. 19. As shown in FIG. 20, the IL 169, the gate dielectric layer 170, and the gate electrode layer 172 are capped between the dielectric spacers 144 along the X direction. The IL 169, the gate dielectric layer 170, and the gate electrode layer 172 may be disposed between vertically adjacent cap layers 210 in the PMOS region 202 and between vertically adjacent first semiconductor layers 106 in the NMOS region 204.

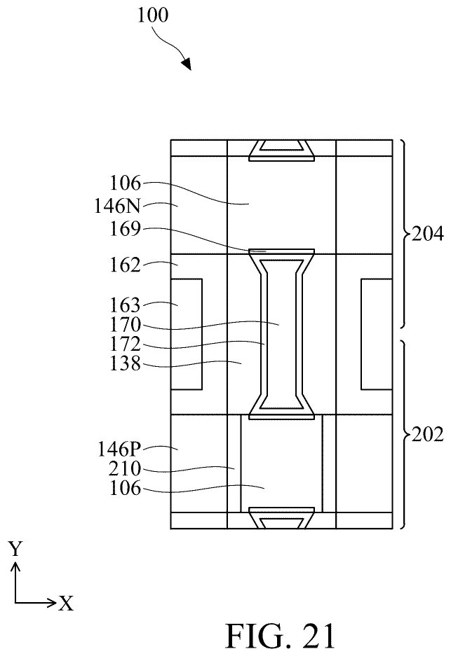

FIG. 21 is a cross-sectional top view of one of various stages of manufacturing the semiconductor device structure 100, in accordance with some embodiments. As shown in FIG. 21, the dimension of the first semiconductor layer 106 along the Y direction is not reduced as a result of using the dielectric materials 143, 243. In some embodiments, the dimension of the first semiconductor layer 106 along the Y direction is reduced from about 0 nm to about 2.5 nm.

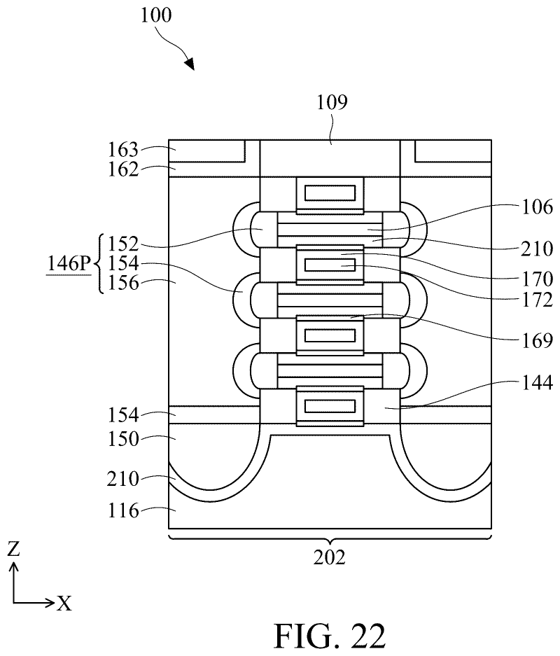

FIG. 22 is a cross-sectional side view of one of various stages of manufacturing the semiconductor device structure 100 taken along line A-A of FIG. 5, in accordance with alternative embodiments. In some embodiments, after the formation of the dielectric spacers 144, a semiconductor layer 150 is formed on the portion of the cap layer 210 that is formed on the substrate portions 116, as shown in FIG. 21. In some embodiments, the semiconductor layer 150 includes undoped silicon. The semiconductor layer 150 may be first formed on semiconductor surfaces, such as on the portions of the cap layer 210 formed on the substrate portions 116 and the portions of the cap layer 210 and first semiconductor layers 106 located between vertically adjacent dielectric spacers 144, by epitaxy. In some embodiments, the semiconductor layer 150 is crystalline silicon. A subsequent etch process is performed to remove the portions of the semiconductor layer 150 formed on the portions of the cap layer 210 and first semiconductor layers 106 located between vertically adjacent dielectric spacers 144. In some embodiments, the semiconductor layer 150 has a thickness ranging from about 5 nm to about 50 nm along the Z direction. In some embodiments, the semiconductor layer 150 is also formed in the NMOS region 204.

Next, a mask layer (not shown) is formed in the NMOS region 204 (not shown), the cap layer 210 and the first semiconductor layers 106 are laterally recessed to form cavities between vertically adjacent dielectric spacers 144, and a first semiconductor material 152 is formed in the cavities. The first semiconductor material 152 may be epitaxially grown from the cap layer 210 and the first semiconductor layers 106. In some embodiments, the first semiconductor material 152 is also formed on the semiconductor layer 150, and a subsequent anisotropic etch process is performed to remove the portion of the first semiconductor material 152 formed on the semiconductor layer 150. In some embodiments, a dielectric layer (not shown) is formed on the semiconductor layer 150, and the first semiconductor material 152 is not formed on the dielectric layer. The first semiconductor material 152 may include any suitable semiconductor material, such as SiGe or SiP. P-type dopants, such as boron (B), may also be included in the first semiconductor material 152. In some embodiments, the first semiconductor material 152 has a first dopant concentration. The first semiconductor material 152 may reduce junction overlap and may reduce resistance.

Next, a second semiconductor material 154 is formed from the first semiconductor material 152 and the semiconductor layer 150. The second semiconductor material 154 may be epitaxially grown from the first semiconductor material 152 and the semiconductor layer 150. In some embodiments, the second semiconductor material 154 includes any suitable semiconductor material, such as Si, SiGe, or Ge, and the second semiconductor material 154 includes a p-type dopant. The second semiconductor material 154 includes a second dopant concentration greater than the first dopant concentration. Next, a third semiconductor material 156 is formed from the second semiconductor material 154. The third semiconductor material 156 may include the same semiconductor material as the second semiconductor material 154 and may have a third dopant concentration greater than the second dopant concentration. The first, second, and third semiconductor materials 152, 154, 156 may together form the S/D region 146P, as shown in FIG. 22.

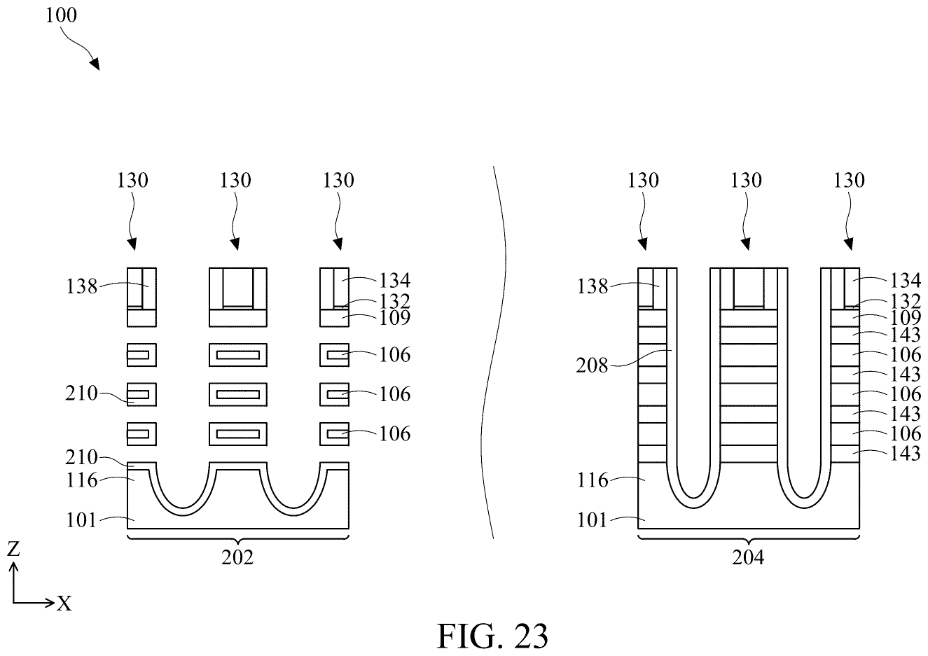

FIGS. 23, 24, 25, 26, and 27 are cross-sectional side views of various stages of manufacturing the semiconductor device structure 100 taken along line A-A of FIG. 5, in accordance with alternative embodiments. As shown in FIG. 23, the cap layer 210 is formed on the trimmed first semiconductor layers 106 in the PMOS region 202. The semiconductor device structure 100 shown in FIG. 23 is at the same manufacturing stage as the semiconductor device structure 100 shown in FIG. 12.

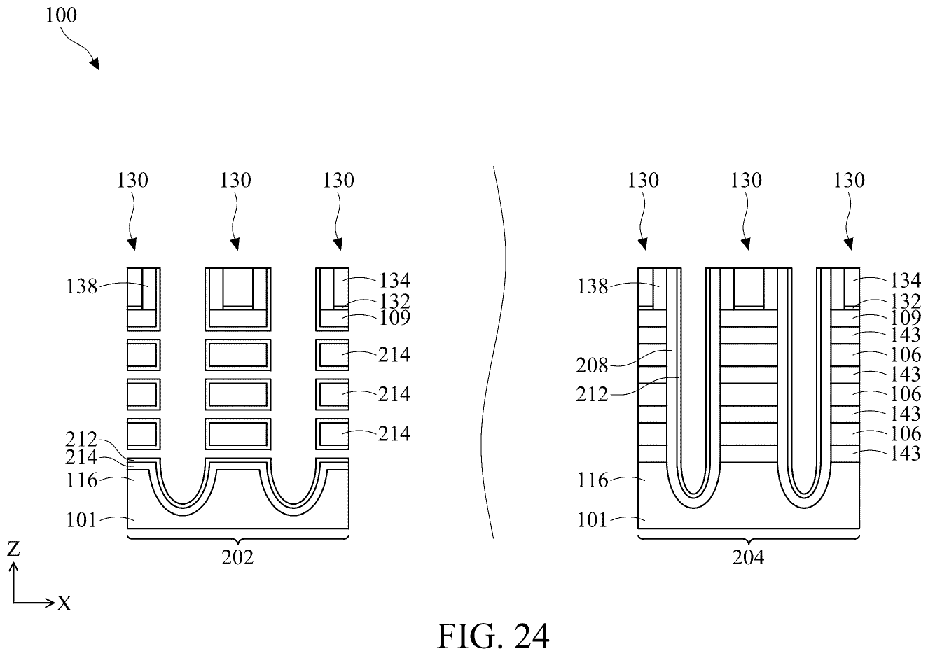

Next, as shown in FIG. 24, a dielectric cap layer 212 is formed on the exposed surfaces of the semiconductor device structure 100 in the PMOS region 202 and the NMOS region 204. The dielectric cap layer 212 may surround the cap layer 210, which surrounds the first semiconductor layers 106 in the PMOS region 202. The dielectric cap layer 212 may be formed on the cap layer 210 disposed on the substrate portion 116 in the PMOS region 202. The dielectric cap layer 212 is formed on the mask layer 208 in the NMOS region 204. After forming the dielectric cap layer 212, a thermal process, such as an annealing process, is performed to form the semiconductor layers 214. In some embodiments, the first semiconductor layers 106 is made of Si, and the cap layer 210 is made of SiGe. The annealing process drives the Ge in the cap layer 210 into the first semiconductor layers 106. As a result, the semiconductor layer 214 with a uniform Ge concentration is formed. The semiconductor layer 214 may be also formed on the substrate portion 116, as shown in FIG. 24. The annealing process may have a processing temperature ranging from about 900 degrees Celsius to about 1000 degrees Celsius and may be performed for about 10 seconds to about 100 seconds. The dielectric cap layer 212 prevents the flow and deformation of the cap layer 210 during the thermal process due to the low melting point of the cap layer 210. In some embodiments, the semiconductor layer 214 includes SiGe with about five atomic percent to about 50 atomic percent of Ge. With the semiconductor layer 214, the channel region is made of SiGe. As a result, work function is easier to adjust, charge carrier is increased, and current is increased. After the thermal process, the dielectric cap layer 212 is removed from the PMOS region 202 and the NMOS region 204.

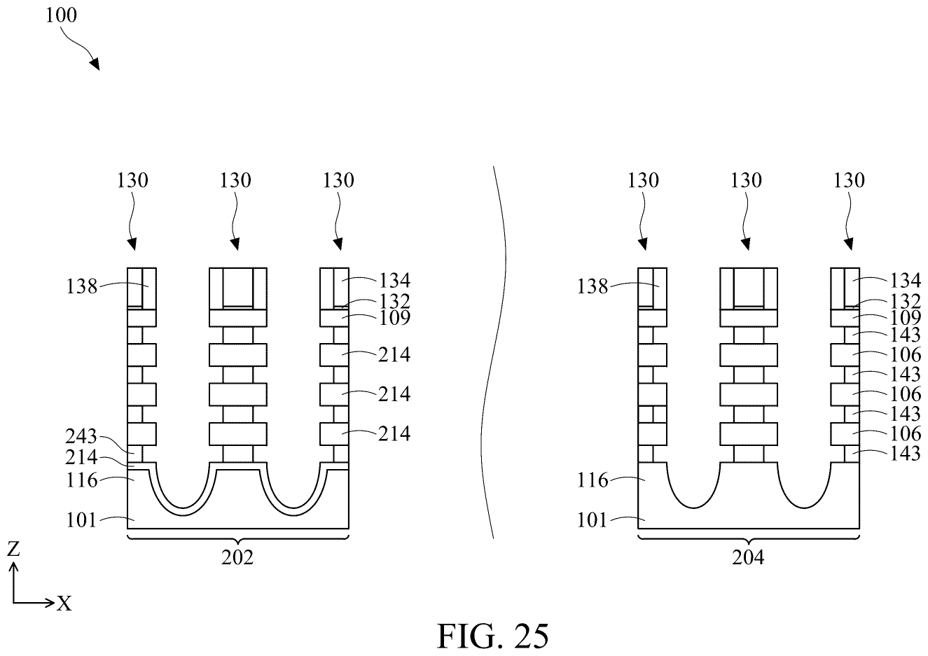

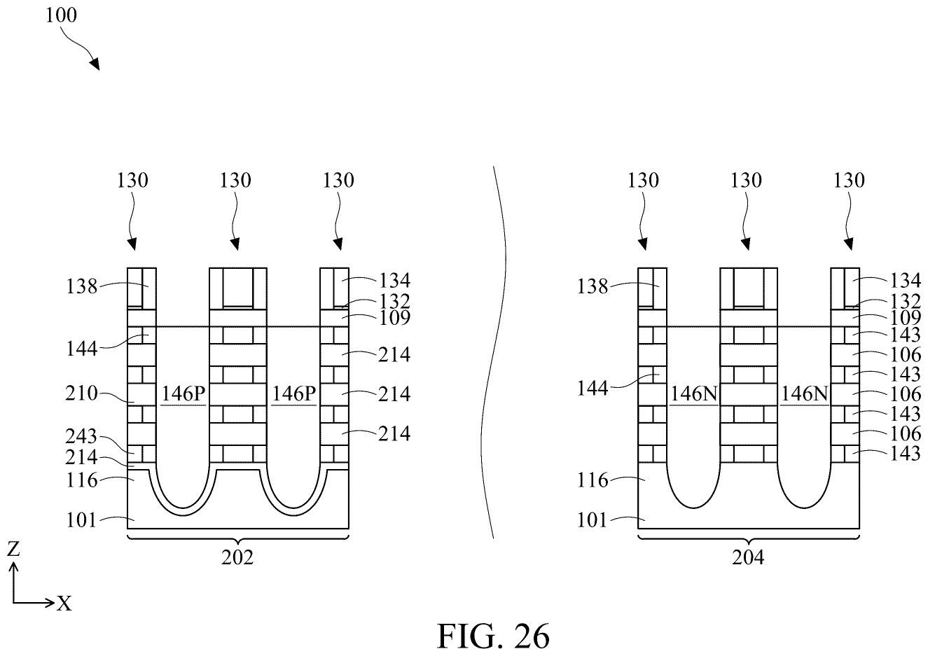

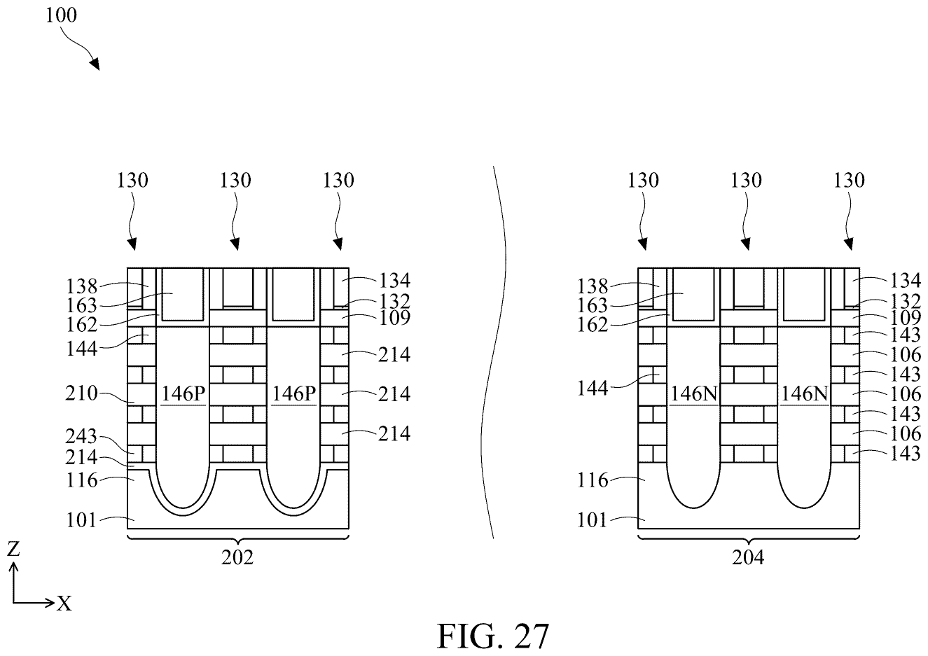

In FIG. 25, processes described in FIG. 13 are performed to form the dielectric material 243 in the PMOS region 202 and the dielectric material 143 in the NMOS region 204. As shown in FIG. 25, cavities are formed between vertically adjacent semiconductor layers 214 in the PMOS region 202 and between vertically adjacent first semiconductor layers 106 in the NMOS region 204. Next, as shown in FIG. 26, the dielectric spacers 144 are formed in the cavities in the PMOS region 202 and the NMOS region 204, the S/D regions 146P are formed in the PMOS region 202, and the S/D regions 146N are formed in the NMOS region 204. The processes to form the dielectric spacers 144 and the S/D regions 146P, 146N may be the same as the processes described in FIG. 14. In FIG. 27, the CESL 162 and the ILD layer 163 are formed over the S/D regions 146P, 146N.

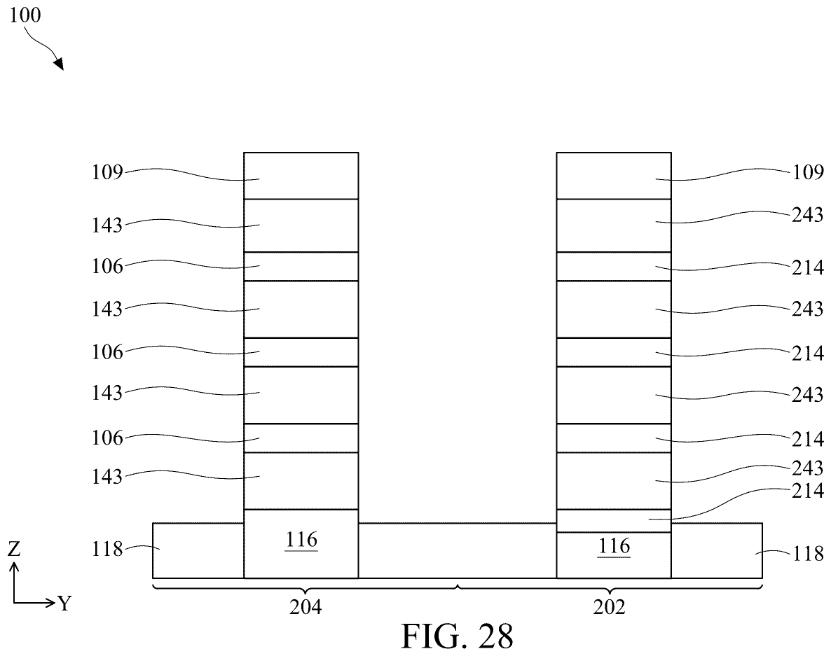

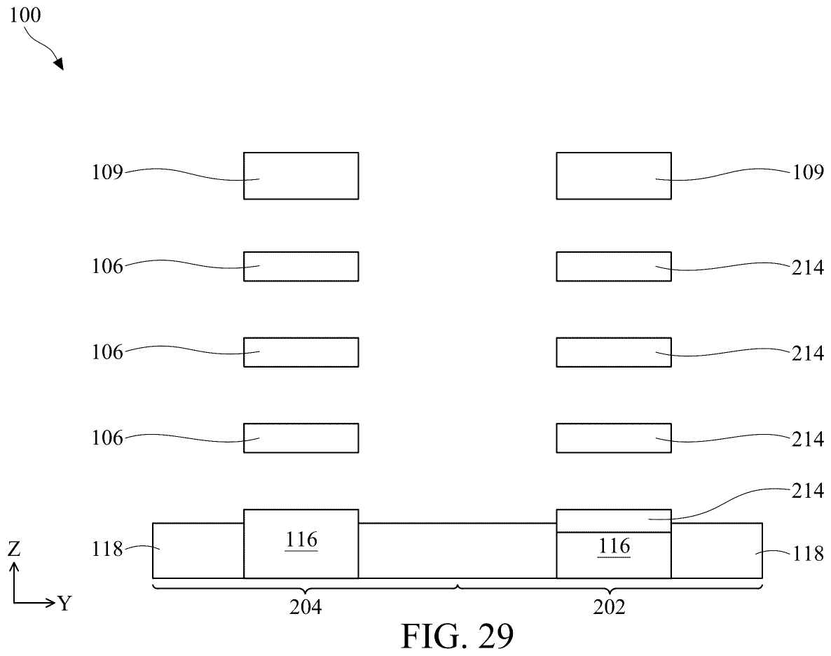

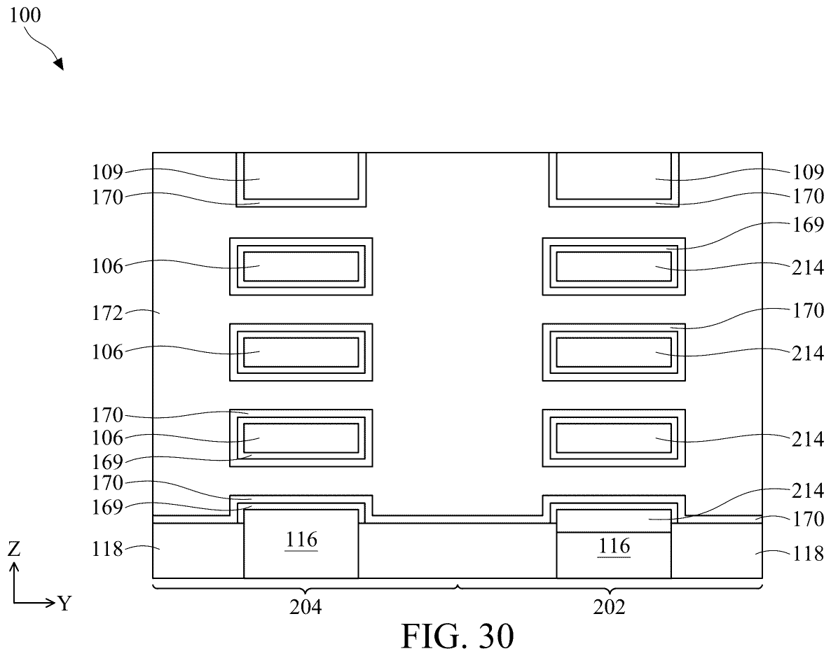

FIGS. 28, 29, and 30 are cross-sectional side views of various stages of manufacturing the semiconductor device structure 100 taken along line B-B of FIG. 5, in accordance with alternative embodiments. As shown in FIG. 28, the sacrificial gate electrode layer 134 and the sacrificial gate dielectric layer 132 are removed. Next, as shown in FIG. 29, the dielectric materials 143, 243 are removed. The IL 169 is then formed on the semiconductor layer 214 over the substrate portion 116 and around the semiconductor layers 214 in the PMOS region 202 and on the substrate portion 116 and around the first semiconductor layers 106 in the NMOS region 204, as shown in FIG. 30. The gate dielectric layer 170 is formed over the IL 169 and the insulating material 118, and the gate electrode layer 172 is formed on the gate dielectric layer 170.

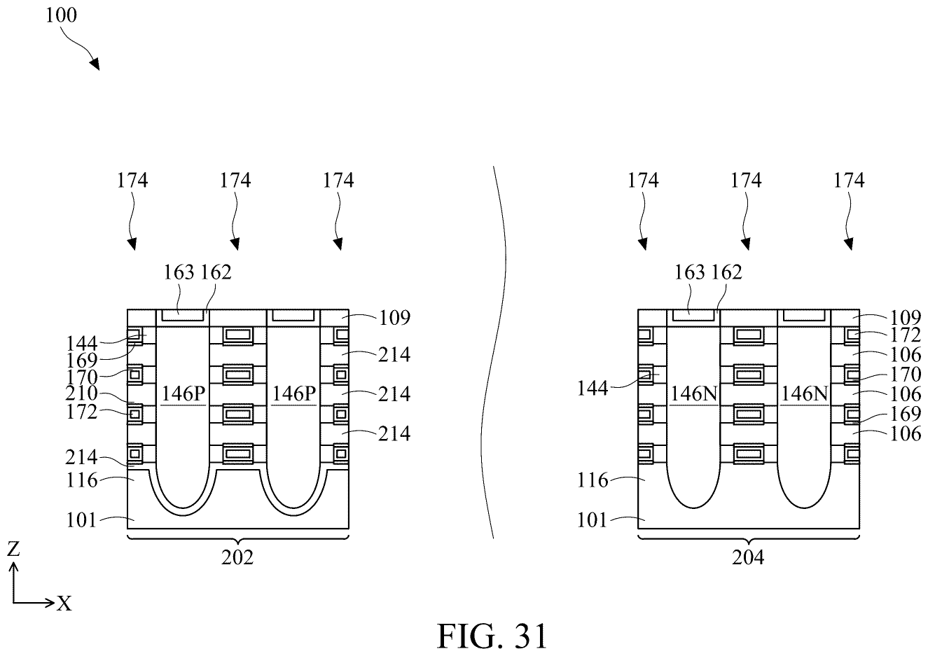

FIG. 31 is a cross-sectional side view of one of various stages of manufacturing the semiconductor device structure 100 taken along line A-A of FIG. 5, in accordance with some embodiments. FIG. 31 illustrates the semiconductor device structure 100 at the same manufacturing stage as the semiconductor device structure 100 shown in FIG. 30. As shown in FIG. 31, the IL 169, the gate dielectric layer 170, and the gate electrode layer 172 are capped between the dielectric spacers 144 along the X direction. The IL 169, the gate dielectric layer 170, and the gate electrode layer 172 may be disposed between vertically adjacent semiconductor layers 214 in the PMOS region 202 and between vertically adjacent first semiconductor layers 106 in the NMOS region 204.

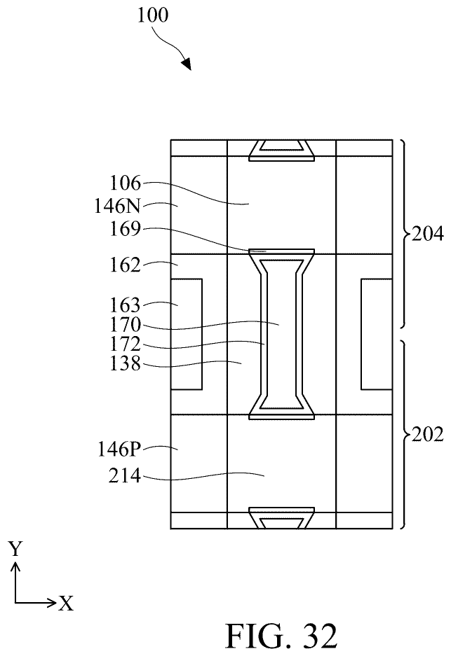

FIG. 32 is a cross-sectional top view of one of various stages of manufacturing the semiconductor device structure 100, in accordance with some embodiments. As shown in FIG. 32, the dimension of the first semiconductor layer 106 along the Y direction is not reduced as a result of using the dielectric materials 143, 243. In some embodiments, the dimension of the first semiconductor layer 106 along the Y direction is reduced from about 0 nm to about 2.5 nm.

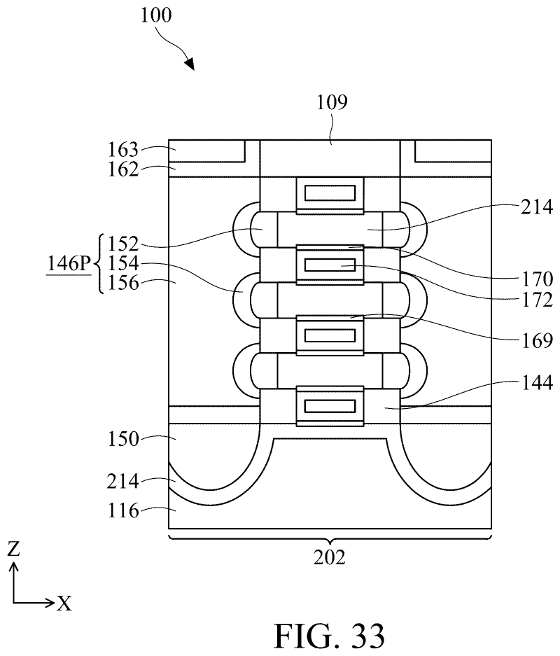

FIG. 33 is a cross-sectional side view of one of various stages of manufacturing the semiconductor device structure 100 taken along line A-A of FIG. 5, in accordance with alternative embodiments. In some embodiments, after the formation of the dielectric spacers 144, the semiconductor layer 150 is formed on the portion of the semiconductor layer 214 that is formed on the substrate portions 116, as shown in FIG. 33.

Next, the semiconductor layers 214 are laterally recessed to form cavities between vertically adjacent dielectric spacers 144 in the PMOS region 202, and the first semiconductor material 152 is formed in the cavities. Then, the second semiconductor material 154 is formed from the first semiconductor material 152 and the semiconductor layer 150, and the third semiconductor material 156 are formed from the second semiconductor material 154, as shown in FIG. 33.

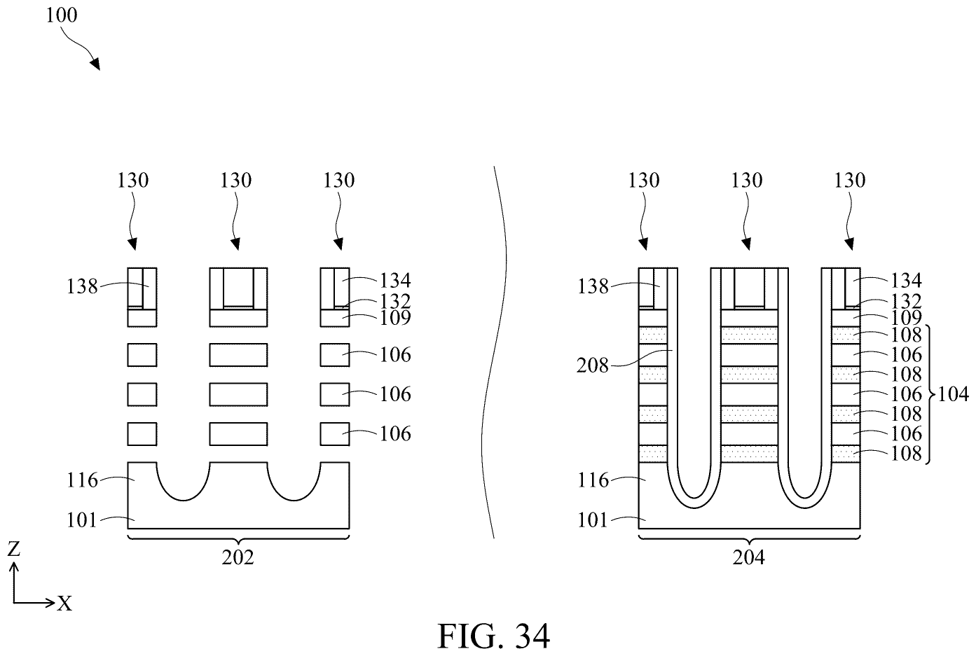

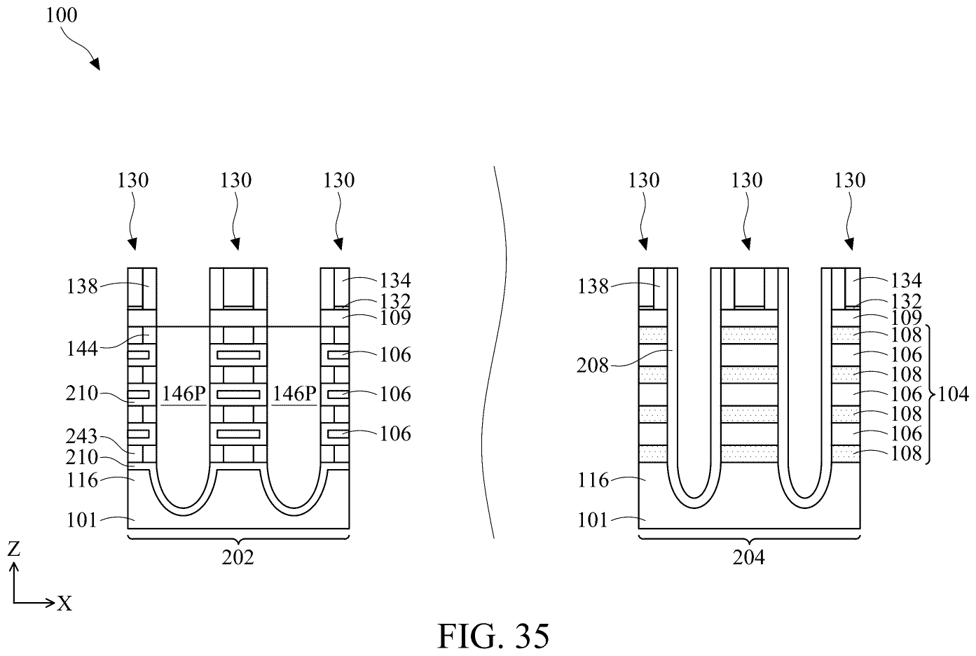

FIGS. 34, 35, 36, and 37 are cross-sectional side views of various stages of manufacturing the semiconductor device structure 100 taken along line A-A of FIG. 5, in accordance with alternative embodiments. As shown in FIG. 34, after recessing the second portions of the fin structures 112 not covered by the sacrificial gate structure 130 and the spacers 138 as described in FIG. 8, the mask layer 208 is formed in the NMOS region 204. In other words, the processes described in FIG. 9 are omitted. The second semiconductor layers 108 remain in the NMOS region 204, as shown in FIG. 34. Next, processes described in FIGS. 10 through 14 in the PMOS region 202 are performed, while the mask layer 208 remain in the NMOS region 204. As shown in FIG. 35, the cap layer 210, the dielectric material 243, the dielectric spacers 144, and the S/D regions 146P are formed in the PMOS region 202, while the mask layer 208 is disposed in the NMOS region 204.

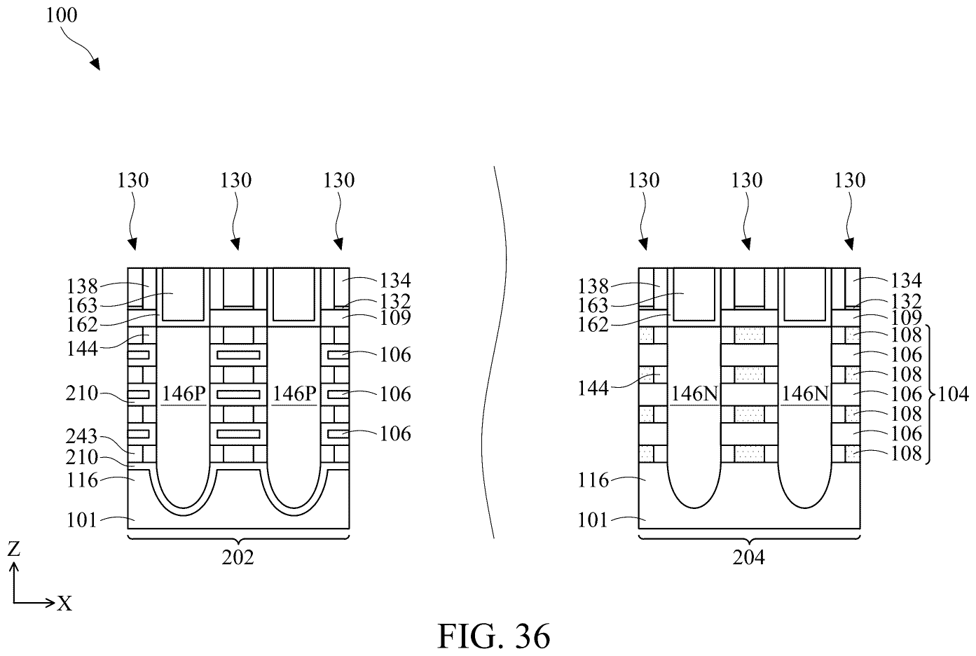

Next, a mask layer (not shown) is formed in the PMOS region 202, and processes described in FIGS. 10 through 14 in the NMOS region 204 are performed. As shown in FIG. 36, the second semiconductor layers 108 are laterally recessed to form cavities, the dielectric spacers 144 are formed in the cavities, and the S/D regions 146N are formed over the substrate portion 116 in the NMOS region 204, while the mask layer (not shown) is disposed in the PMOS region 202.

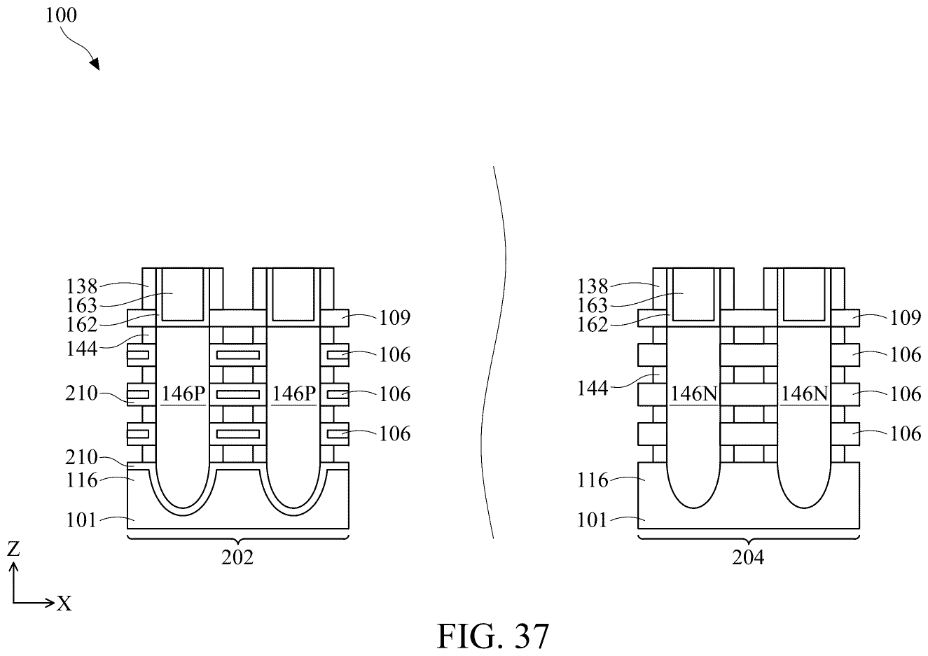

In FIG. 36, the CESL 162 and the ILD layer 163 are formed in the PMOS region 202 and the NMOS region 204. Next, a mask layer (not shown) is formed in the NMOS region 204, and the sacrificial gate structures 130 and the dielectric material 243 in the PMOS region 202 are removed, as shown in FIG. 37. Next, a mask layer (not shown) is formed in the PMOS region 202, the mask layer formed in the NMOS region 204 is removed, and the sacrificial gate structures 130 and the second semiconductor layers 108 in the NMOS region 204 are removed, as shown in FIG. 37. During the removal of the second semiconductor layers 108, the first semiconductor layers 106 may be also recessed in the Z direction and the Y direction. The gate structures 174 are then formed in the PMOS region 202 and the NMOS region 204, as shown in FIG. 20.

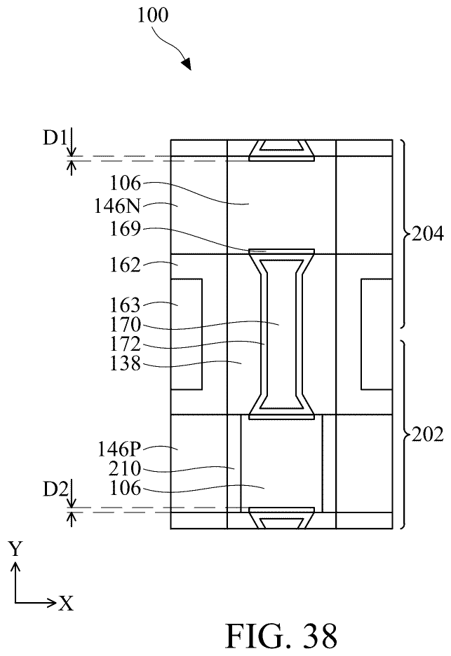

FIG. 38 is a cross-sectional top view of one of various stages of manufacturing the semiconductor device structure 100, in accordance with some embodiments. As described above, the first semiconductor layers 106 in the NMOS region 204 are recessed during the removal of the second semiconductor layers 108. As shown in FIG. 38, the first semiconductor layer 106 located in the NMOS region 204 is recessed in the Y direction by a distance D1. In some embodiments, the distance D1 ranges from about 2.5 nm to about 5 nm. The first semiconductor layer 106 located in the PMOS region 202 may be recessed in the Y direction by a distance D2 less than the distance D2 as a result of using the dielectric material 243. The distance D2 may range from about 0 nm to about 2.5 nm.

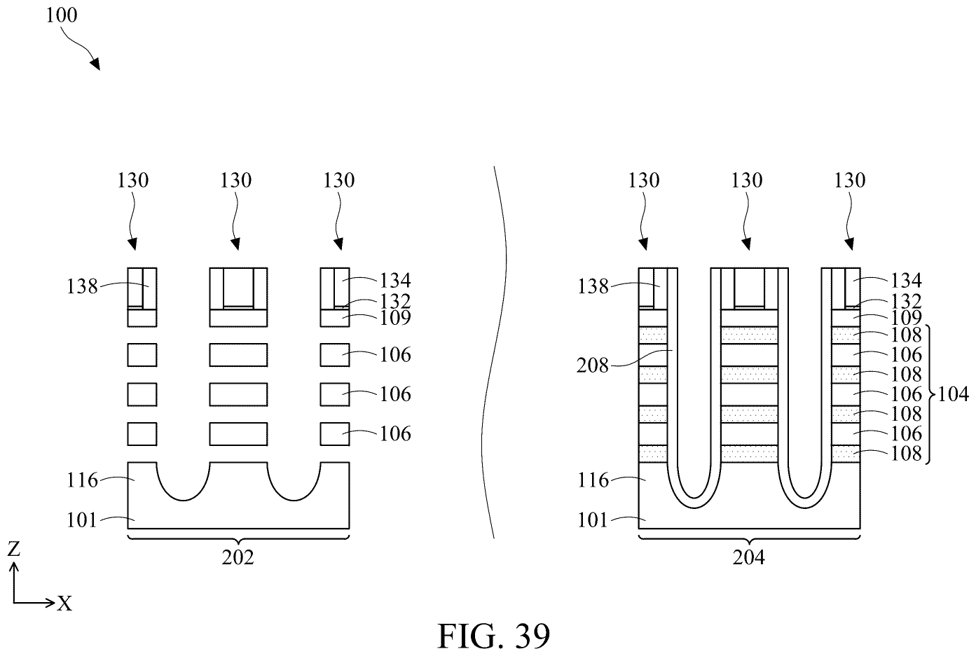

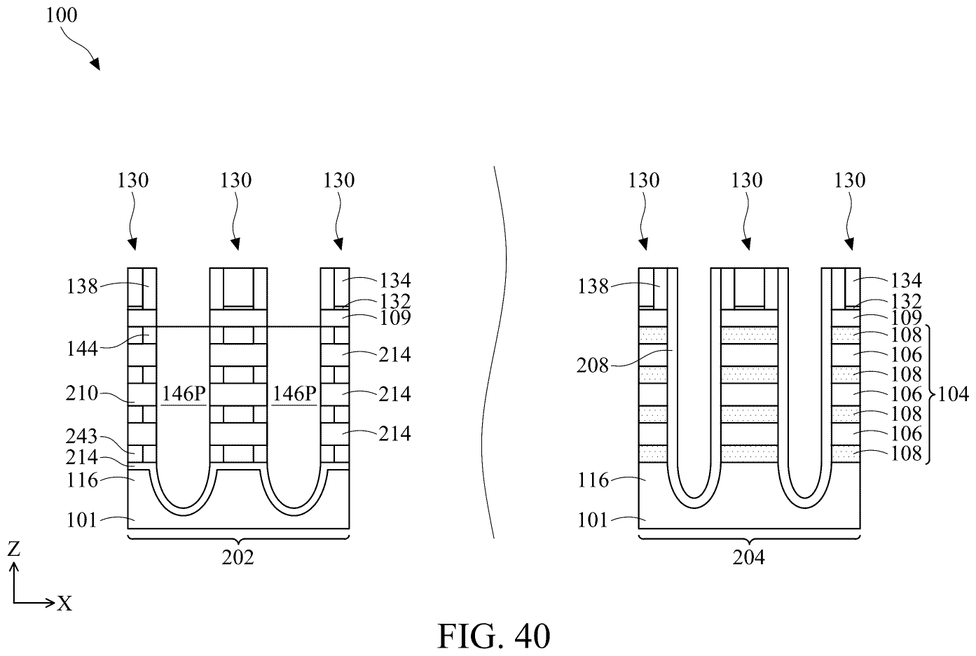

FIGS. 39, 40, 41, and 42 are cross-sectional side views of various stages of manufacturing the semiconductor device structure 100 taken along line A-A of FIG. 5, in accordance with alternative embodiments. As shown in FIG. 39, after recessing the second portions of the fin structures 112 not covered by the sacrificial gate structure 130 and the spacers 138 as described in FIG. 8, the mask layer 208 is formed in the NMOS region 204. In other words, the processes described in FIG. 9 are omitted. The second semiconductor layers 108 remain in the NMOS region 204, as shown in FIG. 39. Next, processes described in FIGS. 23 through 26 in the PMOS region 202 are performed, while the mask layer 208 remain in the NMOS region 204. As shown in FIG. 40, the dielectric material 243, the dielectric spacers 144, the semiconductor layers 214, and the S/D regions 146P are formed in the PMOS region 202, while the mask layer 208 is disposed in the NMOS region 204.

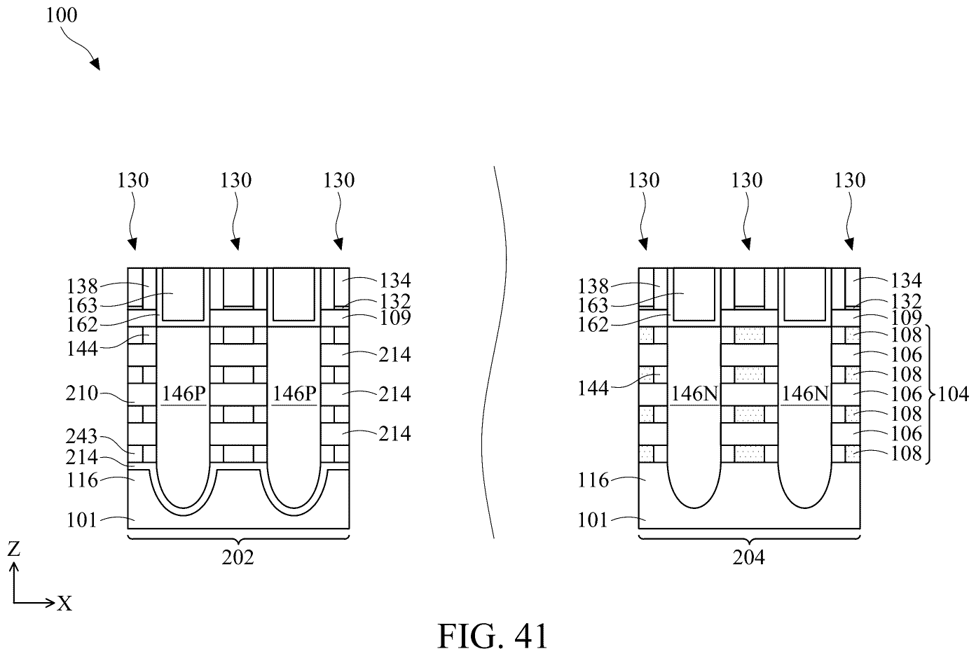

Next, a mask layer (not shown) is formed in the PMOS region 202, and processes described in FIGS. 23 through 26 in the NMOS region 204 are performed. As shown in FIG. 41, the second semiconductor layers 108 are laterally recessed to form cavities, the dielectric spacers 144 are formed in the cavities, and the S/D regions 146N are formed over the substrate portion 116 in the NMOS region 204, while the mask layer (not shown) is disposed in the PMOS region 202.

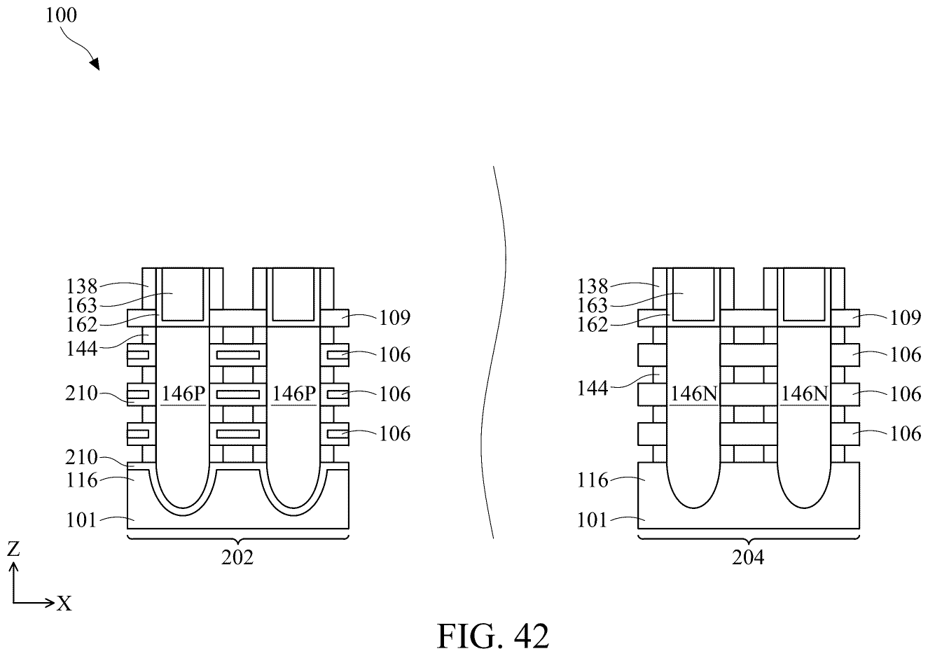

In FIG. 41, the CESL 162 and the ILD layer 163 are formed in the PMOS region 202 and the NMOS region 204. Next, a mask layer (not shown) is formed in the NMOS region 204, and the sacrificial gate structures 130 and the dielectric material 243 in the PMOS region 202 are removed, as shown in FIG. 42. Next, a mask layer (not shown) is formed in the PMOS region 202, the mask layer formed in the NMOS region 204 is removed, and the sacrificial gate structures 130 and the second semiconductor layers 108 in the NMOS region 204 are removed, as shown in FIG. 42. During the removal of the second semiconductor layers 108, the first semiconductor layers 106 may be also recessed in the Z direction and the Y direction. The gate structures 174 are then formed in the PMOS region 202 and the NMOS region 204, as shown in FIG. 20.

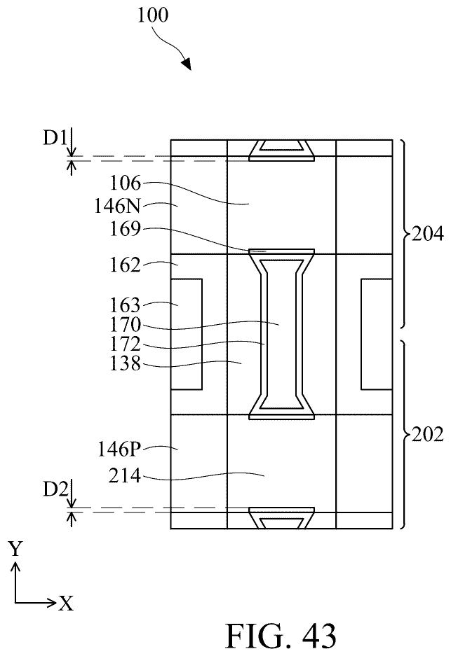

FIG. 43 is a cross-sectional top view of one of various stages of manufacturing the semiconductor device structure 100, in accordance with some embodiments. As described above, the first semiconductor layers 106 in the NMOS region 204 are recessed during the removal of the second semiconductor layers 108. As shown in FIG. 43, the first semiconductor layer 106 located in the NMOS region 204 is recessed in the Y direction by the distance D1. The semiconductor layer 214 located in the PMOS region 202 may be recessed in the Y direction by the distance D2 less than the distance D2 as a result of using the dielectric material 243.

Embodiments of the present disclosure provide a semiconductor device structure and methods of forming the same. The structure includes a semiconductor layer 106 surrounded by a cap layer 210 as a channel region in a PMOS region 202 and a semiconductor layer 106 as a channel region in an NMOS region 204. Some embodiments may achieve advantages. For example, the cap layer 210 may include SiGe, which can simplify metal gate patterning (e.g., more work function material options). Furthermore, boron diffusion is more difficult in SiGe than in Si, and thus it is easier to control the concentration distribution of boron to be sharp at interface between the source/drain region and the SiGe channel.

An embodiment is a semiconductor device structure. The structure includes a first semiconductor layer disposed in a first region and a second semiconductor layer surrounding the first semiconductor layer in the first region. The first and second semiconductor layers comprise different materials. The structure further includes a first gate electrode layer surrounding a portion of the second semiconductor layer, a first source/drain region electrically connected to the second semiconductor layer, and a second source/drain region electrically connected to the second semiconductor layer. The second semiconductor layer is disposed between the first and second source/drain regions.

Another embodiment is a semiconductor device structure. The structure includes a first semiconductor layer disposed over a substrate portion and a second semiconductor layer disposed on the substrate portion below the first semiconductor layer. The first and second semiconductor layers include a same material, and the second semiconductor layer and the substrate portion include different materials. The structure further includes a first source/drain region disposed on the second semiconductor layer and a second source/drain region disposed on the second semiconductor layer. The first semiconductor layer is disposed between the first and second source/drain regions.

A further embodiment is a method. The method includes forming a sacrificial gate structure over a first portion of a fin structure, and the fin structure includes alternating first and second semiconductor layers. The method further includes recessing a second portion of the fin structure to expose a substrate portion, removing the second semiconductor layers in a first region, trimming the first semiconductor layers in the first region, depositing a cap layer around the first semiconductor layers in the first region, and forming first and second source/drain regions on opposite sides of the cap layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first semiconductor layer disposed in a first region;
a second semiconductor layer surrounding the first semiconductor layer in the first region, wherein the first and second semiconductor layers comprise different materials;
a first gate electrode layer surrounding a portion of the second semiconductor layer;
a first source/drain region electrically connected to the second semiconductor layer; and
a second source/drain region electrically connected to the second semiconductor layer, wherein the second semiconductor layer is disposed between the first and second source/drain regions.

2. The semiconductor device structure of claim 1, further comprising an interfacial layer disposed between the second semiconductor layer and the first gate electrode layer and a gate dielectric layer disposed between the interfacial layer and the first gate electrode layer.

3. The semiconductor device structure of claim 2, wherein the interfacial layer surrounds the first and second semiconductor layers.

4. The semiconductor device structure of claim 2, further comprising a first dielectric spacer disposed between the first source/drain region and the first gate electrode layer and a second dielectric spacer disposed between the second source/drain region and the first gate electrode layer.

5. The semiconductor device structure of claim 1, further comprising a third semiconductor layer disposed on a substrate portion, wherein the first and second source/drain regions are disposed on the third semiconductor layer.

6. The semiconductor device structure of claim 1, wherein the first semiconductor layer comprises Si, and the second semiconductor layer comprises SiGe.

7. The semiconductor device structure of claim 6, wherein the second semiconductor layer has about five atomic percent to about 60 atomic percent of germanium.

8. The semiconductor device structure of claim 1, further comprising a fourth semiconductor layer disposed in a second region and a second gate electrode layer surrounding a portion of the fourth semiconductor layer.

9. The semiconductor device structure of claim 8, wherein the first region is a PMOS region, and the second region is an NMOS region.

10. A semiconductor device structure, comprising:
a first semiconductor layer disposed over a substrate portion;
a second semiconductor layer disposed on the substrate portion below the first semiconductor layer, wherein the first and second semiconductor layers comprise a same material, and the second semiconductor layer and the substrate portion comprise different materials;
a first source/drain region disposed on the second semiconductor layer; and
a second source/drain region disposed on the second semiconductor layer, wherein the first semiconductor layer is disposed between the first and second source/drain regions.

11. The semiconductor device structure of claim 10, wherein the first and second semiconductor layers comprise SiGe.

12. The semiconductor device structure of claim 11, wherein the substrate portion comprises Si.

13. The semiconductor device structure of claim 11, wherein first and second semiconductor layers each has a substantially uniform Ge concentration.

14. The semiconductor device structure of claim 10, further comprising a gate electrode layer surrounding a portion of the first semiconductor layer, wherein the gate electrode layer is disposed over the second semiconductor layer.

15. The semiconductor device structure of claim 14, further comprising a gate dielectric layer and an interfacial layer disposed between the first and second semiconductor layers, wherein the interfacial layer is in contact with the first and second semiconductor layers.

16. A method for forming a semiconductor device structure, comprising:
forming a sacrificial gate structure over a first portion of a fin structure, wherein the fin structure comprises alternating first and second semiconductor layers;
recessing a second portion of the fin structure to expose a substrate portion;
removing the second semiconductor layers in a first region;
trimming the first semiconductor layers in the first region;
depositing a cap layer around the first semiconductor layers in the first region; and
forming first and second source/drain regions on opposite sides of the cap layer.

17. The method of claim 16, further comprising replacing the second semiconductor layers with a dielectric material in a second region before removing the second semiconductor layers in the first region.

18. The method of claim 17, further comprising depositing a mask layer in the second region, wherein the mask layer is formed on the first semiconductor layers and the dielectric material.

19. The method of claim 16, further comprising depositing a mask layer in the second region before removing the second semiconductor layers in the first region, wherein the mask layer is formed on the first semiconductor layers and second semiconductor layers.

20. The method of claim 16, further comprising performing an annealing process on the cap layer to form third semiconductor layers, wherein the third semiconductor layers and the first semiconductor layers comprise different materials.
